(19) United States
(12) Patent Application Publication
(10) Pub. No.: US 2011/0186868 A1
(43) Pub. Date: Aug. 4, 2011

(54) LED PACKAGE

(75) Inventors: Gen Watari, Fukuoka-ken (JP); Satoshi Shimizu, Fukuoka-ken (JP); Hiroaki Oshio, Fukuoka-ken (JP); Tatsuo Tonedachi, Fukuoka-ken (JP); Kazuhisa Iwashita, Fukuoka-ken (JP); Tetsuro Komatsu, Fukuoka-ken (JP); Teruo Takeuchi, Fukuoka-ken (JP); Iwao Matsumoto, Fukuoka-ken (JP)

(73) Assignee: KABUSHIKI KAISHA TOSHIBA, Tokyo (JP)

(21) Appl. No.: 12/886,911

(22) Filed: Sep. 21, 2010

(30) Foreign Application Priority Data
Jan. 29, 2010 (JP) 2010-019779
Aug. 23, 2010 (JP) 2010-186398

(51) Int. Cl. H01L 33/50; H01L 33/62

(52) U.S. Cl. 257/88; 257/99; 257/98; 257/E33.066; 257/E33.071

(57) ABSTRACT

According to one embodiment, an LED package includes a first and a second lead frame, an LED chip and a resin body. The first and second lead frames are apart from each other. The LED chip is provided above the first and second lead frames, and has one terminal connected to the first lead frame and another terminal connected to the second lead frame. The wire connects the one terminal to the first lead frame. The resin body covers the first and second lead frames, the LED chip, and the wire. The first lead frame includes a base portion and a plurality of extending portions. As viewed from above, a bonding position of the wire is located inside one of polygonal regions connecting between roots of the two or more of the extending portions. An appearance of the resin body is a part of an appearance of the LED package.

### CROSS-REFERENCE TO RELATED APPLICATIONS

This application is based upon and claims the benefit of priority from the prior Japanese Patent Application No. 2010-019779, filed on Jan. 29, 2010 and the prior Japanese Application No.2010-186398, filed on Aug. 23, 2010; the entire contents of which are incorporated herein by reference.

### FIELD

Embodiments described herein relate generally to an LED (Light Emitting Diode) package.

### BACKGROUND

In a conventional LED package with an LED chip mounted thereon, in order to control the light distribution and enhance the extraction efficiency of light from the LED package, a cup-shaped enclosure made of a white resin is provided, the LED chip is mounted on the bottom surface of the enclosure, and a transparent resin is filled inside the enclosure to bury the LED chip. The enclosure is often formed from a polyamide-based thermoplastic resin.

However, recently, with the expanding application of LED packages, there is a growing demand for LED packages with higher durability. On the other hand, increase in the output power of LED chips results in increasing light and heat emitted from the LED chip, which makes the resin portion sealing the LED chip more susceptible to degradation. Furthermore, with the expanding application of LED packages, there is demand for further cost reduction.

### BRIEF DESCRIPTION OF THE DRAWINGS

FIG. 1 is a perspective view illustrating an LED package according to a first embodiment;

FIG. 2A is a sectional view taken along line A-A′ shown in FIG. 1, and FIG. 2B is a sectional view taken along line B-B′ shown in FIG. 1;

FIG. 3 is a plan view illustrating lead frames in the first embodiment;

FIG. 4 is a plan view illustrating the lead frames and the like of the first embodiment;

FIG. 5 is a flow chart illustrating a method for manufacturing an LED package according to the first embodiment;

FIGS. 6A to 8B are process sectional views illustrating the method for manufacturing an LED package according to the first embodiment;

FIG. 9A is a plan view illustrating a lead frame sheet in the first embodiment, and FIG. 9B is a partially enlarged plan view illustrating the element region of this lead frame sheet;

FIG. 10 is a graph illustrating the influence which the ratio of resin thickness W to the plate thickness t of the lead frame exerts on the appearance of the LED package, where the value of the ratio W/t is taken on the horizontal axis, and the determination result of the appearance of the LED package after dicing is taken on the vertical axis;

FIGS. 11A to 11H are process sectional views illustrating the method for forming the lead frame sheet in a variation of the first embodiment;

FIG. 12 is a perspective view illustrating an LED package according to a second embodiment;

FIG. 13 is a side view illustrating the LED package according to the second embodiment;

FIG. 14 is a perspective view illustrating an LED package according to a third embodiment;

FIG. 15 is a sectional view illustrating the LED package according to the third embodiment;

FIG. 16 is a perspective view illustrating an LED package according to a fourth embodiment;

FIG. 17 is a sectional view illustrating the LED package according to the fourth embodiment;

FIG. 18 is a perspective view illustrating an LED package according to a fifth embodiment;

FIG. 19 is a sectional view illustrating the LED package according to the fifth embodiment;

FIG. 20 is a perspective view illustrating an LED package according to a sixth embodiment;

FIG. 21 is a sectional view illustrating the LED package according to the sixth embodiment;

FIG. 22 is a plan view illustrating an LED package according to a seventh embodiment;

FIG. 23 is a sectional view illustrating the LED package according to the seventh embodiment;

FIG. 24A is a plan view illustrating an LED package according to an eighth embodiment, and FIG. 24B is a sectional view thereof;

FIG. 25 is a perspective view illustrating an LED package according to a first variation of the eighth embodiment;

FIG. 26A is a plan view illustrating lead frames, LED chips, and wires of the LED package according to the first variation of the eighth embodiment, FIG. 26B is a bottom view illustrating the LED package, and FIG. 26C is a sectional view illustrating the LED package;

FIG. 27 is a perspective view illustrating an LED package according to a second variation of the eighth embodiment;

FIG. 28A is a plan view illustrating an LED package according to a third variation of the eighth embodiment, and FIG. 28B is a sectional view thereof;

FIG. 29A is a plan view illustrating an LED package according to a fourth variation of the eighth embodiment, and FIG. 29B is a sectional view thereof;

FIG. 30A is a plan view illustrating an LED package according to a fifth variation of the eighth embodiment, and FIG. 30B is a sectional view thereof;

FIG. 31A is a plan view illustrating an LED package according to a sixth variation of the eighth embodiment, and FIG. 31B is a sectional view thereof; and

FIGS. 32A to 32E are plan views illustrating the element region of the lead frame sheet used in a seventh variation of the eighth embodiment;

FIG. 33 is an upper perspective view illustrating an LED package according to a ninth embodiment;

FIG. 34 is a lower perspective view illustrating the LED package according to the ninth embodiment;

FIG. 35 is a top view illustrating the LED package according to the ninth embodiment;

FIG. 36 is a bottom view illustrating the LED package according to the ninth embodiment;

FIG. 37 is a side view viewed in an X direction illustrating the LED package according to the ninth embodiment;

FIG. 38 is a side view viewed in a Y direction illustrating the LED package according to the ninth embodiment; and

FIG. 39 is a plan view illustrating a lead frame of the ninth embodiment.

### DETAILED DESCRIPTION

In general, according to one embodiment, an LED package includes a first and a second lead frame, an LED chip and a resin body. The first and second lead frames are apart from each other. The LED chip is provided above the first and second lead frames, and has one terminal connected to the first lead frame and another terminal connected to the second lead frame. The wire connects the one terminal to the first lead frame. The resin body covers the first and second lead frames, the LED chip, and the wire. The first lead frame includes a base portion and a plurality of extending portions. As viewed from above, a bonding position of the wire is located inside one of polygonal regions connecting between roots of the two or more of the extending portions. An appearance of the resin body is a part of an appearance of the LED package.

The embodiments will now be described with reference to the drawings.

At the outset, a first embodiment is described.

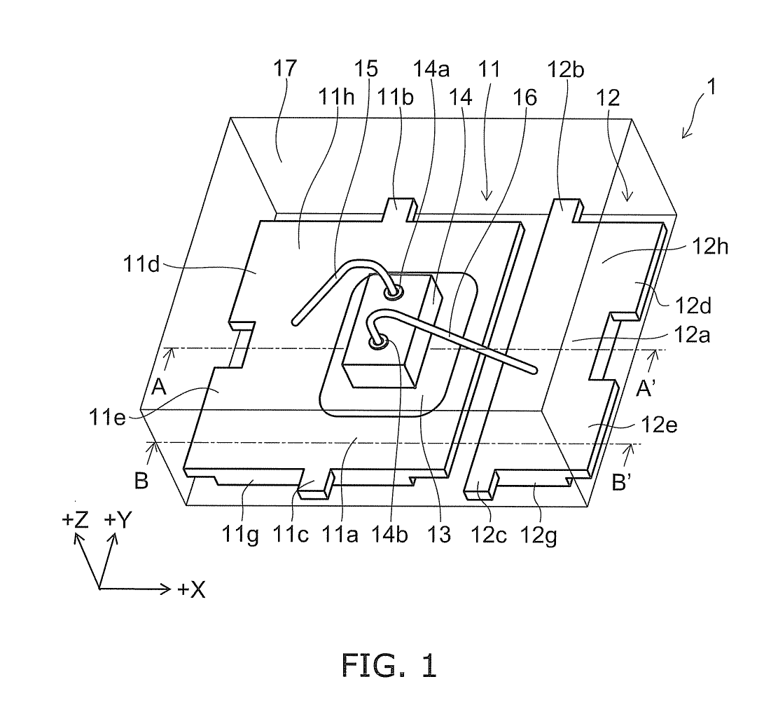

FIG. 1 is a perspective view illustrating an LED package according to this embodiment.

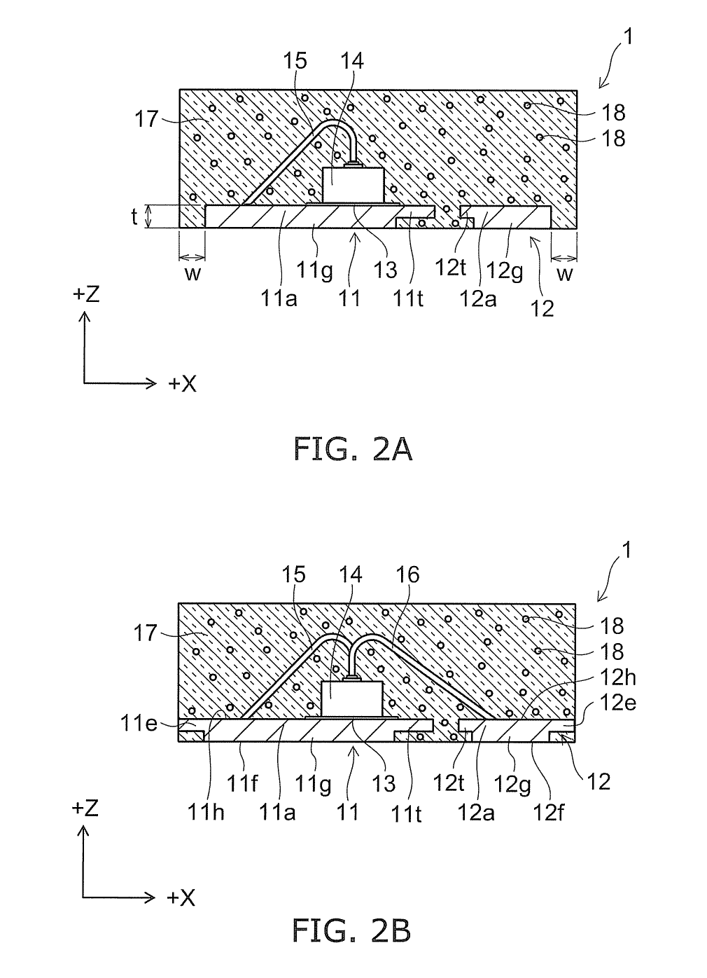

FIG. 2A is a sectional view taken along line A-A′ shown in FIG. 1, and FIG. 2B is a sectional view taken along line B-B′ shown in FIG. 1.

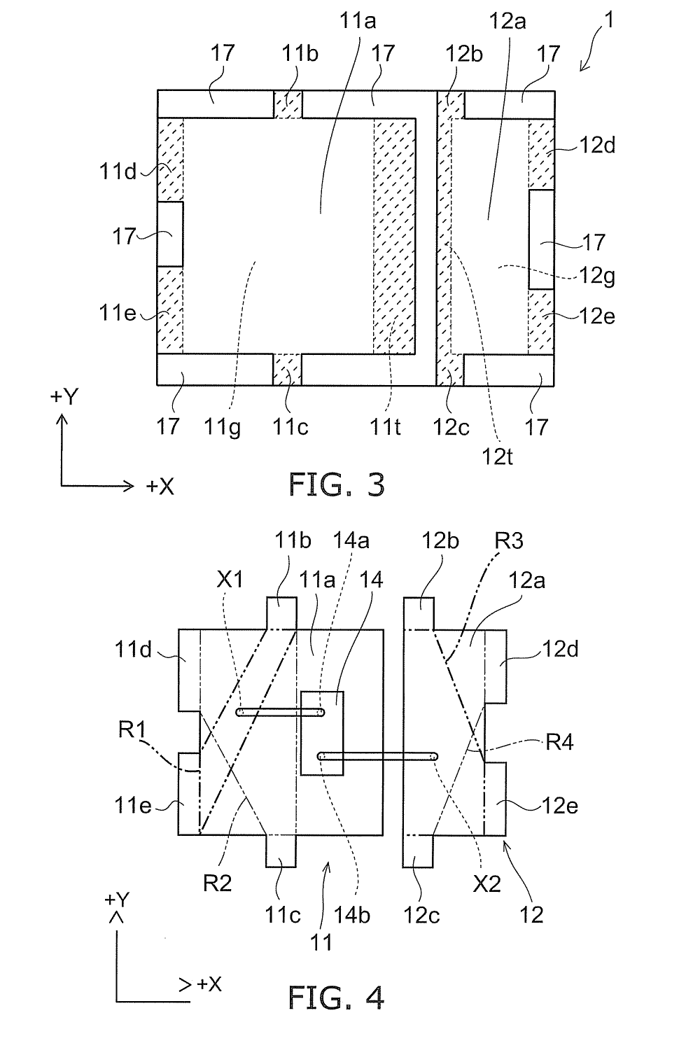

FIG. 3 is a plan view illustrating lead frames in this embodiment.

FIG. 4 is a plan view illustrating the lead frames and the like of this embodiment.

As shown in FIGS. 1 to 4, the LED package 1 according to this embodiment includes a pair of lead frames 11 and 12. The lead frames 11 and 12 are shaped like flat plates, being flush with and apart from each other. The lead frames 11 and 12 are made of the same conductive material, illustratively in a configuration such that a silver plating layer is formed on the upper surface and lower surface of a copper plate. However, on the edge surface of the lead frames 11 and 12, the silver plating layer is not formed, but the copper plate is exposed.

In the following, for convenience of description, an XYZ orthogonal coordinate system is herein introduced. Of the directions parallel to the upper surface of the lead frames 11 and 12, the direction from the lead frame 11 to the lead frame 12 is defined as +X direction. Of the directions perpendicular to the upper surface of the lead frames 11 and 12, the upward direction, i.e., the direction to where an LED chip 14 described later is mounted as viewed from the lead frame, is defined as +Z direction. Furthermore, one of the directions orthogonal to both the +X direction and the +Z direction is defined as +Y direction. In addition, the directions opposite to the +X direction, +Y direction, and +Z direction are referred to as −X direction, −Y direction, and −Z direction, respectively. Furthermore, the “+X direction” and “−X direction”, for instance, are also collectively and simply referred to as “X direction”.

The lead frame 11 includes one base portion 11a, which is rectangular as viewed in the Z direction, and four extending portions 11b, 11c, 11d, 11e extend from this base portion 11a. The extending portion 11b extends from the X direction center of the +Y direction facing edge of the base portion 11a toward the +Y direction. The extending portion 11c extends from the X direction center of the −Y direction facing edge of the base portion 11a toward the −Y direction. Thus, the extending portions 11b-11e extend from three different sides of the base portion 11a. The positions of the extending portions 11b and 11c in the X direction are the same. The extending portions 11d and 11e extend from both ends of the −X direction facing edge of the base portion 11a toward the −X direction.

As compared with the lead frame 11, the lead frame 12 has a shorter length in the X direction and the same length in the Y direction. The lead frame 12 includes one base portion 12a, which is rectangular as viewed in the Z direction, and four extending portions 12b, 12c, 12d, 12e extend from this base portion 12a. The extending portion 12b extends from the −X direction end of the +Y direction facing edge of the base portion 12a toward the +Y direction. The extending portion 12c extends from the −X direction end of the −Y direction facing edge of the base portion 12a toward the −Y direction. The extending portions 12d and 12e extend from both ends of the +X direction facing edge of the base portion 12a toward the +X direction. Thus, the extending portions 12b-12e extend from three different sides of the base portion 12a. The width of the extending portions 11d and 11e of the lead frame 11 may be either equal to or different from the width of the extending portions 12d and 12e of the lead frame 12. However, if the width of the extending portions 11d and 11e is different from the width of the extending portions 12d and 12e, it is easier to distinguish between the anode and the cathode.

A protrusion 11g is formed at the X direction center of the base portion 11a on a lower surface 11f of the lead frame 11. Thus, the lead frame 11 has two thickness levels. That is, the X direction center of the base portion 11a, i.e., the portion where the protrusion 11g is formed, is a relatively thick plate portion. Both X direction ends of the base portion 11a and the extending portions 11b-11e are relatively thin plate portions. In FIG. 3, the portion of the base portion 11a where the protrusion 11g is not formed is shown as a thin plate portion 11t. Likewise, a protrusion 12g is formed at the X direction center of the base portion 12a on a lower surface 12f of the lead frame 12. Thus, the lead frame 12 also has two thickness levels. The X direction center of the base portion 12a is relatively thick because the protrusion 12g is formed thereat and forms a thick plate portion. Both X direction ends of the base portion 12a and the extending portions 12b-12e are relatively thin plate portions. In FIG. 3, the portion of the base portion 12a where the protrusion 12g is not formed is shown as a thin plate portion 12t. In other words, notches extending in the Y direction along the edges of the base portions 11a and 12a are formed in the lower surface of both X-direction ends of the base portions 11a and 12a. In FIG. 3, the relatively thin portions in the lead frames 11 and 12, i.e., the thin plate portions and the extending portions, are hatched with dashed lines.

The protrusions 11g and 12g are formed in regions apart from the mutually opposed edges of the lead frames 11 and 12, and regions including these edges are the thin plate portions 11t and 12t. An upper surface 11h of the lead frame 11 and an upper surface 12h of the lead frame 12 are flush with each other, and the lower surface of the protrusion 11g of the lead frame 11 and the lower surface of the protrusion 12g of the lead frame 12 are flush with each other. The position of the upper surface of each extending portion in the Z direction coincides with the position of the upper surface of the lead frames 11 and 12. Hence, each extending portion is located on the same XY plane.

The upper surface 11h and lower surface 11f of the lead frame 11, and the upper surface 12h and lower surface 12f of the lead frame 12 have a roughness of 1.20 or more. The “roughness” refers to the fractal dimension calculated by the box counting method for the curve occurring in a cross section containing the normal to the surface under evaluation and corresponding to this surface. For instance, a completely flat hypothetical surface has a roughness of “1”. Specifically, the aforementioned curve is measured by an atomic force microscope. The box counting method is applied with the box size ranging from 50 nm to 5 μm and the pixel size set to 1/100 or less thereof.

A die mount material 13 is attached to part of the region corresponding to the base portion 11a in the upper surface 11h of the lead frame 11. In this embodiment, the die mount material 13 may be either conductive or insulative. In the case where the die mount material 13 is conductive, the die mount material 13 is formed illustratively from a silver paste, solder, eutectic solder or the like. In the case where the die mount material 13 is insulative, the die mount material 13 is formed illustratively from a transparent resin paste.

An LED chip 14 is provided on the die mount material 13. That is, the die mount material secures the LED chip 14 to the lead frame 11 so that the LED chip 14 is mounted on the lead frame 11. The LED chip 14 illustratively includes semiconductor layers made of gallium nitride (GaN) and the like stacked on a sapphire substrate, and is illustratively shaped like a rectangular solid, with terminals 14a and 14b provided on its upper surface. The LED chip 14 illustratively emits blue light by being supplied with a voltage between the terminal 14a and the terminal 14b.

One end of a wire 15 is bonded to the terminal 14a of the LED chip 14. The wire 15 is drawn out from the terminal 14a to the +Z direction (directly upward) and bent toward the direction between the −X direction and the −Z direction, and the other end of the wire 15 is bonded to the upper surface 11h of the lead frame 11. Thus, the terminal 14a is connected to the lead frame 11 via the wire 15. On the other hand, one end of a wire 16 is bonded to the terminal 14b. The wire 16 is drawn out from the terminal 14b to the +Z direction and bent toward the direction between the +X direction and the −Z direction, and the other end of the wire 16 is bonded to the upper surface 12h of the lead frame 12. Thus, the terminal 14b is connected to the lead frame 12 via the wire 16. The wires 15 and 16 are formed from a metal, such as gold or aluminum.

As shown in FIG. 4, the bonding position X1 where the other end of the wire 15 is bonded to the lead frame 11 is located inside the polygonal region R1 connecting between the root of the extending portion 11b and the root of the extending portion 11e. Furthermore, the bonding position X1 is located inside the polygonal region R2 connecting among the roots of the extending portions 11b, 11c, and 11d. On the other hand, the bonding position X2 where the other end of the wire 16 is bonded to the lead frame 12 is located inside the polygonal region R3 connecting among the roots of the extending portions 12b, 12c, and 12e. Furthermore, the bonding position X2 is located also inside the polygonal region R4 connecting among the roots of the extending portions 12b, 12c, 12d.

Furthermore, the LED package 1 includes a transparent resin body 17. The transparent resin body 17 is formed from a transparent resin, such as silicone resin. Here, “transparent” includes translucent as well. The appearance of the transparent resin body 17 is a rectangular solid, covering the lead frames 11 and 12, the die mount material 13, the LED chip 14, and the wires 15 and 16, and forms the appearance of the LED package 1. Note that, other parts of the appearance of the LED package 1 are formed by the extending portions and the protrusions of the lead frames 11 and 12. Part of the lead frame 11 and part of the lead frame 12 are exposed on the lower surface and side surface of the transparent resin body 17.

More specifically, in the lower surface 11f of the lead frame 11, the lower surface of the protrusion 11g is exposed on the lower surface of the transparent resin body 17, and the tip edge surfaces of the extending portions 11b-11e are exposed on the side surface of the transparent resin body 17. On the other hand, the entire upper surface 11h, the region of the lower surface 11f except the protrusion 11g, the side surface of the protrusion 11g, and the edge surface of the base portion 11a of the lead frame 11 are covered with the transparent resin body 17. Likewise, in the lead frame 12, the lower surface of the protrusion 12g is exposed on the lower surface of the transparent resin body 17, the tip edge surface of the extending portions 12b-12e is exposed on the side surface of the transparent resin body 17, and the entire upper surface 12h, the region of the lower surface 12f except the protrusion 12g, the side surface of the protrusion 12g, and the edge surface of the base portion 12a are covered with the transparent resin body 17. In the LED package 1, the lower surfaces of the protrusions 11g and 12g exposed on the lower surface of the transparent resin body 17 are external electrode pads. As described above, the transparent resin body 17 has a rectangular shape when seen from above, and the tip edge surfaces of the aforementioned multiple extending portions of each of the lead frames 11 and 12 are exposed on a corresponding one of the three different side surfaces of the transparent resin body 17. Note that in this specification, the term “cover” is a concept including both a case where one that covers is in contact with one that is covered and a case where the two are not in contact with each other.

Furthermore, as shown in FIGS. 2A and 2B, the shortest distance W from the edge surface of the base portions 11a and 12a to the side surface of the transparent resin body 17 is 50% or more of the maximum thickness, i.e., the plate thickness t of the portion where the protrusions 11g and 12g are formed, of the lead frames 11 and 12. For instance, the plate thickness t of the lead frames 11 and 12 is 100 μm, and the distance W is 50 μm or more, such as 100 μm.

Numerous phosphors 18 are dispersed inside the transparent resin body 17. Each phosphor 18 is particulate, absorbs light emitted from the LED chip 14, and emits light with a longer wavelength. For instance, the phosphor 18 absorbs part of blue light emitted from the LED chip 14 and emits yellow light. Thus, the LED package 1 emits blue light, which is emitted from the LED chip 14 and not absorbed by the phosphor 18, and yellow light emitted from the phosphor 18, resulting in white emission light as a whole. The phosphor 18 like this can illustratively be YAG:Ce. For convenience of illustration, FIGS. 1, 3, and the subsequent figures do not show the phosphor 18. Furthermore, in FIGS. 2A and 2B, the phosphors 18 are shown larger and fewer than in reality.

The phosphor 18 like this can illustratively be a silicate-based phosphor emitting yellow-green, yellow, or orange light. The silicate-based phosphor can be represented by the following general formula:

(2−x−y)SrO.x(Baᵤ,Caᵥ)O.(1−a−b−c−d)SiO₂.aP₂O₅bAl₂O₃cB₂O₃dGeO₂:yEu²⁺

where 0<x, 0.005<y<0.5, x+y≦1.6, 0≦a, b, c, d<0.5, 0<u, 0<v, and u+v=1.

Alternatively, a YAG-based phosphor can also be used as a yellow phosphor. The YAG-based phosphor can be represented by the following general formula:

(RE₁₋ₓSmₓ)₃(Al_{y}Ga_{1-y})₅O₁₂:Ce

where 0≦x<1, 0≦y≦1, and RE is at least one element selected from Y and Gd.

Alternatively, the phosphor 18 can be a mixture of a sialon-based red phosphor and green phosphor. Specifically, the phosphors 18 can be a green phosphor which absorbs blue light emitted from the LED chip 14 and emits green light, and a red phosphor which absorbs blue light and emits red light. The sialon-based red phosphor can illustratively be represented by the following general formula:

(M₁₋ₓ,Rₓ)ₐ₁AlSi_{b1}O_{c1}N_{d1}

where M is at least one metallic element except Si and Al, and preferably at least one of Ca and Sr in particular. R is an emission center element, and preferably Eu in particular. The quantities x, a1, b1, c1, and d1 satisfy 0<x≦1, 0.6<a1<0.95, 2<b1<3.9, 0.25<c1<0.45, and 4<d1<5.7.

A specific example of such a sialon-based red phosphor is given by:

Sr₂Si₇Al₇ON₁₃:Eu²⁺.

The sialon-based green phosphor can illustratively be represented by the following general formula:

(M₁₋ₓ,Rₓ)ₐ₂AlSi_{b2}O_{c2}N_{d2}

where M is at least one metallic element except Si and Al, and preferably at least one of Ca and Sr in particular. R is an emission center element, and preferably Eu in particular. The quantities x, a2, b2, c2, and d2 satisfy 0<x≦1, 0.93<a2<1.3, 4.0<b2<5.8, 0.6<c2<1, and 6<d2<11.

A specific example of such a sialon-based green phosphor is given by:

Sr₃Si₁₃Al₃O₂N₂₁:Eu²⁺.

Next, a method for manufacturing an LED package according to this embodiment is described.

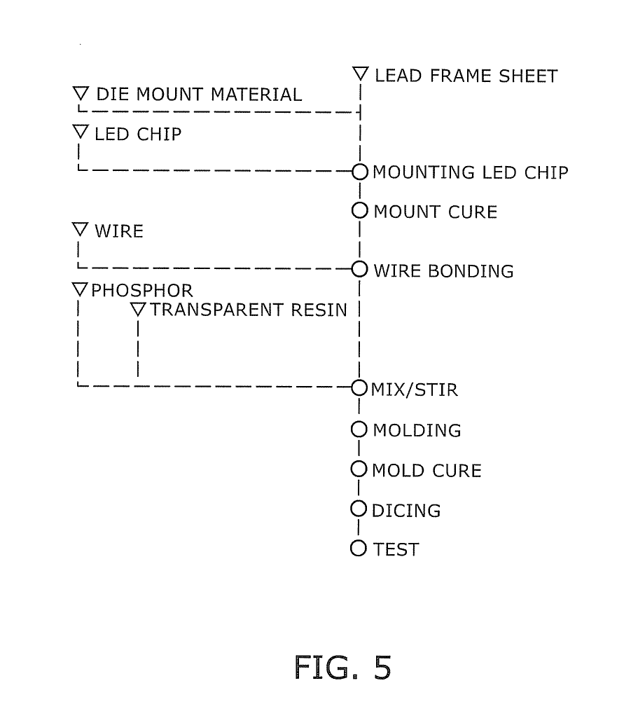

FIG. 5 is a flow chart illustrating the method for manufacturing an LED package according to this embodiment.

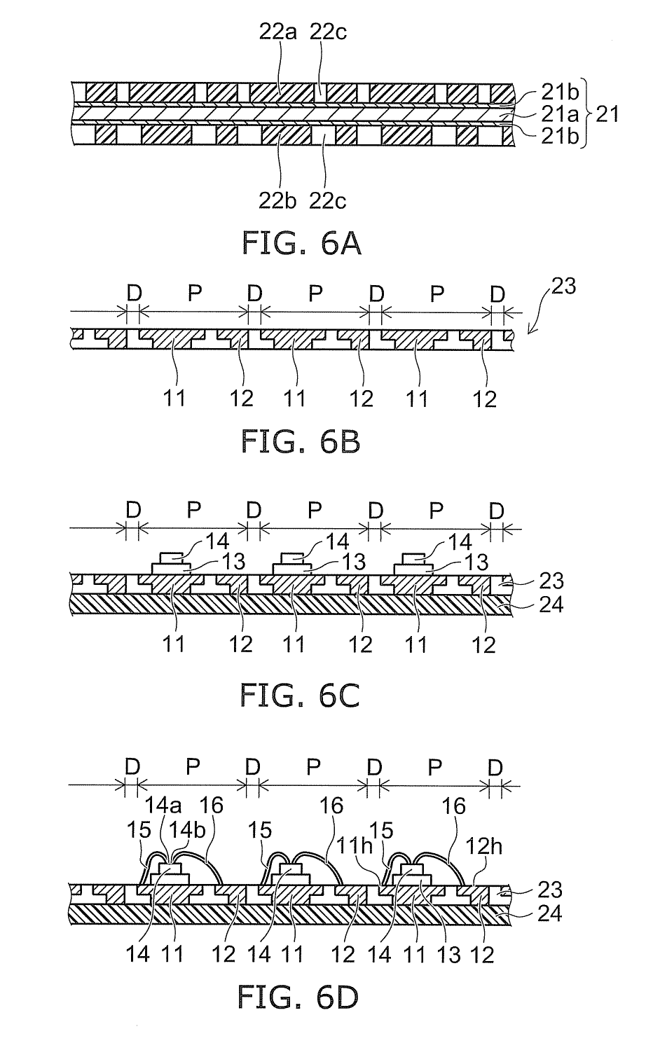

FIGS. 6A to 6D, 7A to 7C, 8A, and 8B are process sectional views illustrating the method for manufacturing an LED package according to this embodiment.

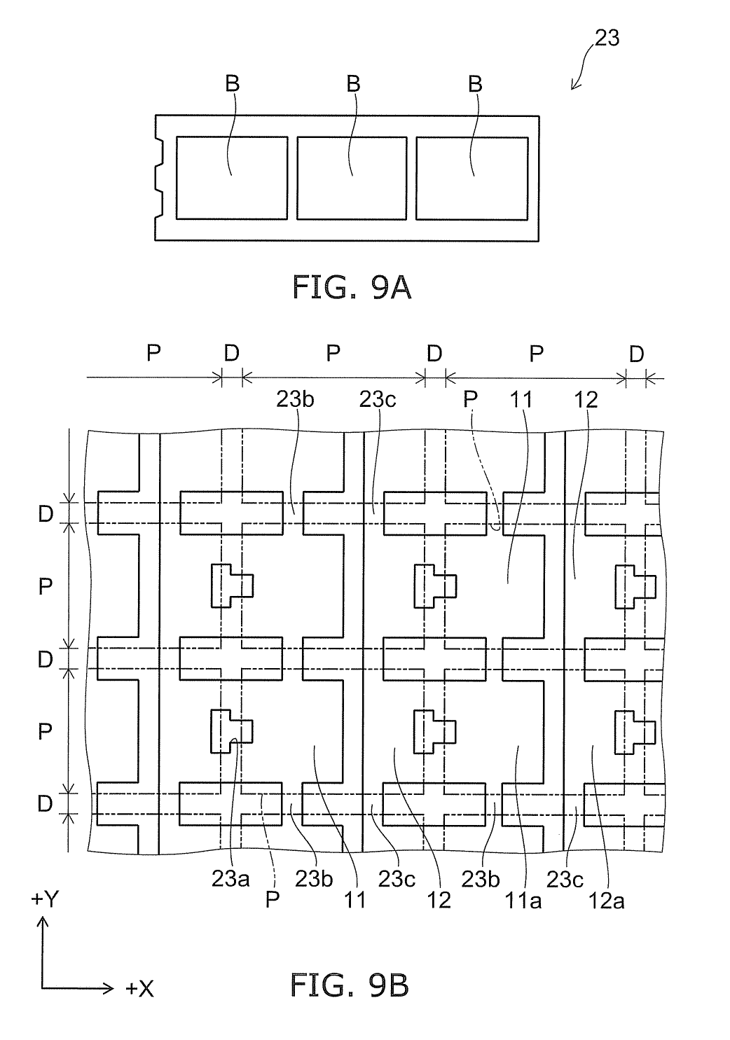

FIG. 9A is a plan view illustrating a lead frame sheet in this embodiment, and FIG. 9B is a partially enlarged plan view illustrating the element region of this lead frame sheet.

First, as shown in FIG. 6A, a conductive sheet 21 made of a conductive material is prepared. This conductive sheet 21 is illustratively a strip-shaped copper plate 21a with the upper and lower surface provided with a silver plating layer 21b. The roughness of the upper surface and lower surface of the conductive sheet 21, i.e., the surface of the silver plating layer 21b, is 1.20 or more. The roughness of the surface of the silver plating layer 21b can be controlled by adjusting the formation condition of the silver plating layer 21b. For instance, in the case where the silver plating layer 21b is formed by an electroplating process, typically, the roughness increases if the current density is increased, if the feed rate for passing the copper plate 21a in the plating bath is slowed down, and if the concentration of the plating liquid is increased.

Next, masks 22a and 22b are formed on the upper and lower surface of this conductive sheet 21. Openings 22c are selectively formed in the masks 22a and 22b. The masks 22a and 22b can be formed illustratively by a printing process.

Next, the conductive sheet 21 with the masks 22a and 22b attached thereto is immersed in an etching liquid, and thereby wet etched. Thus, in the conductive sheet 21, the portion located in the opening 22c is etched and selectively removed. Here, the etching amount is controlled illustratively by adjusting the immersion time so that etching is stopped before the etching from the upper surface side and lower surface side of the conductive sheet 21 each independently penetrates through the conductive sheet 21. Thus, half-etching is performed from the upper and lower surface side. However, the portion etched from both the upper surface side and lower surface side is caused to penetrate through the conductive sheet 21. Subsequently, the masks 22a and 22b are removed.

Thus, as shown in FIGS. 5 and 6B, the copper plate 21a and the silver plating layer 21b are selectively removed from the conductive sheet 21 to form a lead frame sheet 23. For convenience of illustration, in FIG. 6B and the subsequent figures, the copper plate 21a and the silver plating layer 21b are integrally shown as a lead frame sheet 23 without distinction. As shown in FIG. 9A, three blocks B, for instance, are defined in the lead frame sheet 23, and approximately 1000 element regions P, for instance, are defined in each block B. As shown in FIG. 9B, the element regions P are arranged in a matrix, and the portion between the element regions P is a lattice-like dicing region D. In each element region P, a basic pattern including lead frames 11 and 12 apart from each other is formed. In the dicing region D, the conductive material forming the conductive sheet 21 remains so as to connect between the adjacent element regions P.

More specifically, the lead frame 11 and the lead frame 12 are apart from each other in the element region P. However, the lead frame 11 belonging to one element region P is connected to the lead frame 12 belonging to the adjacent element region P located in the −X direction as viewed from the former element region P, and an opening 23a with a shape projected to the +X direction is formed between these frames. Furthermore, the lead frames 11 belonging to the element regions P adjacent in the Y direction are connected to each other via a bridge 23b. Likewise, the lead frames 12 belonging to the element regions P adjacent in the Y direction are connected to each other via a bridge 23c. Thus, from the base portions 11a and 12a of the lead frames 11 and 12, four conductive connecting portions extend to three directions. The connecting portions are made of conductive material, and extend from the base portion of the lead frame 11 or 12 belonging to one element region P to the base portion of the lead frame 11 or 12 belonging to an adjacent device portion P through the dicing region D. Furthermore, half-etching is used to etch the lead frame sheet 23 from its lower surface side so that protrusions 11g and 12g (see FIGS. 2A and 2B) are formed on the lower surface of the lead frames 11 and 12, respectively.

Next, as shown in FIGS. 5 and 6C, a reinforcing tape 24 illustratively made of polyimide is affixed to the lower surface of the lead frame sheet 23. Then, a die mount material 13 is attached onto the lead frame 11 belonging to each element region P of the lead frame sheet 23. For instance, a paste-like die mount material 13 is discharged from a discharger onto the lead frame 11, or transferred onto the lead frame 11 by mechanical means. Next, an LED chip 14 is mounted on the die mount material 13. Next, heat treatment (mount cure) for sintering the die mount material 13 is performed. Thus, the LED chip 14 is mounted on the lead frame 11 via the die mount material 13 in each element region P of the lead frame sheet 23.

Next, as shown in FIGS. 5 and 6D, by ultrasonic bonding, for instance, one end of the wire 15 is bonded to the terminal 14a of the LED chip 14, and the other end is bonded to the upper surface of the lead frame 11. Furthermore, one end of the wire 16 is bonded to the terminal 14b of the LED chip 14, and the other end is bonded to the upper surface 12h of the lead frame 12. Thus, the terminal 14a is connected to the lead frame 11 via the wire 15, and the terminal 14b is connected to the lead frame 12 via the wire 16.

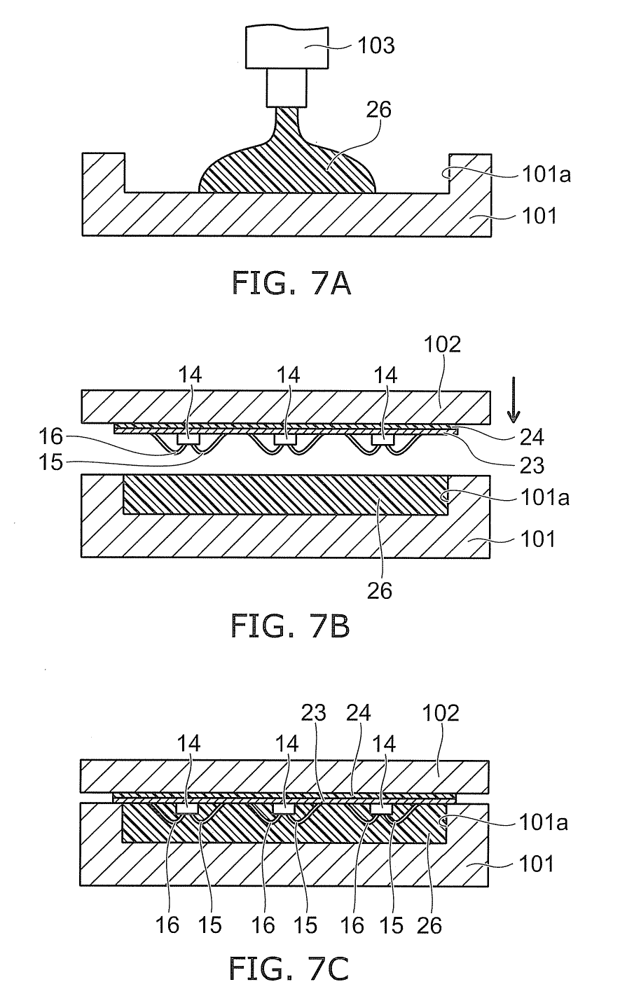

Next, as shown in FIGS. 5 and 7A, a lower mold 101 is prepared. The lower mold 101, in combination with an upper mold 102 described later, forms a set of molds, and a recess 101a shaped like a rectangular solid is formed in the upper surface of the lower mold 101. On the other hand, phosphors 18 (see FIGS. 2A and 2B) are mixed and stirred in a transparent resin such as silicone resin to prepare a liquid or semi-liquid phosphor-containing resin material 26. Then, by a dispenser 103, the phosphor-containing resin material 26 is supplied into the recess 101a of the lower mold 101.

Next, as shown in FIGS. 5 and 7B, the aforementioned lead frame sheet 23 with the LED chips 14 mounted thereon is attached to the lower surface of the upper mold 102 so that the LED chips 14 face downward. Then, the upper mold 102 is pressed to the lower mold 101, and the molds are clamped. Thus, the lead frame sheet 23 is pressed to the phosphor-containing resin material 26. At this time, the phosphor-containing resin material 26 covers the LED chip 14 and the wires 15 and 16, and also penetrates into the etched-away portion of the lead frame sheet 23. Thus, the phosphor-containing resin material 26 is molded. It is preferable that the mold process is performed in a vacuum atmosphere. This prevents bubbles generated in the phosphor-containing resin material 26 from adhering to portions half-etched in the lead frame sheet 23.

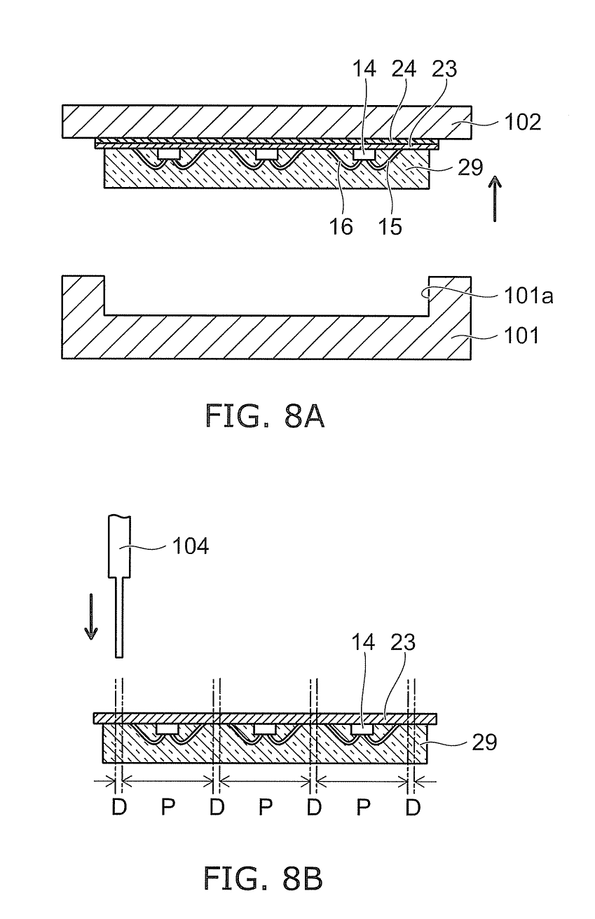

Next, as shown in FIGS. 5 and 7C, heat treatment (mold cure) is performed with the upper surface of the lead frame sheet 23 pressed to the phosphor-containing resin material 26 to cure the phosphor-containing resin material 26. Subsequently, as shown in FIG. 8A, the upper mold 102 is pulled away from the lower mold 101. Thus, a transparent resin plate 29 covering the entire upper surface and part of the lower surface of the lead frame sheet 23 and burying the LED chips 14 and the like is formed. Phosphors 18 (see FIGS. 2A and 2B) are dispersed in the transparent resin plate 29. Next, the reinforcing tape 24 is stripped from the lead frame sheet 23. Thus, the lower surface of the protrusions 11g and 12g (see FIGS. 2A and 2B) of the lead frames 11 and 12 is exposed on the surface of the transparent resin plate 29.

Next, as shown in FIGS. 5 and 8B, by a blade 104, the combined body of the lead frame sheet 23 and the transparent resin plate 29 is diced from the lead frame sheet 23 side, i.e., from the −Z direction side toward the +Z direction. Thus, the portion of the lead frame sheet 23 and the transparent resin plate 29 located in the dicing region D is removed. Consequently, the portion of the lead frame sheet 23 and the transparent resin plate 29 located in the element region P is singulated, and an LED package 1 shown in FIGS. 1 to 2B is manufactured. Incidentally, the assembly of the lead frame sheet 23 and the transparent resin plate 29 may be diced from a side of the transparent resin body 29.

In each LED package 1 after dicing, the lead frames 11 and 12 are separated from the lead frame sheet 23. Furthermore, the transparent resin plate 29 is divided into a transparent resin body 17. The portion of the dicing region D extending in the Y direction passes through the openings 23a of the lead frame sheet 23, and thereby extending portions lid, 11e, 12d, 12e are formed in the lead frames 11 and 12. Furthermore, extending portions 11b and 11c are formed in the lead frame 11 by division of the bridge 23b, and extending portions 12b and 12c are formed in the lead frame 12 by division of the bridge 23c. The tip edge surface of the extending portions 11b-11e and 12b-12e is exposed on the side surface of the transparent resin body 17.

Next, as shown in FIG. 5, various tests are performed on the LED package 1. At this time, the tip edge surface of the extending portions 11b-11e and 12b-12e may be used as a terminal for the tests.

Next, the function and effect of this embodiment are described.

In this embodiment, the dicing surface of the lead frame sheet 23 and the transparent resin plate 29 directly forms the side surface of the LED package 1, and part of the lead frames 11 and 12 is exposed on this side surface. Hence, it is preferable to take measures so that the lead frame is not stripped from the transparent resin body 17 starting from this exposed portion. If the lead frame is stripped from the transparent resin body to form an opening, the characteristics of the LED package are degraded. For instance, the light reflection efficiency decreases due to an air layer formed between the lead frame and transparent resin body, corrosion of the lead frame proceeds due to penetration of moisture and the like from the opening, and the wire is corroded by moisture and the like penetrated from the opening and reaching the wire. For instance, if the silver plating layer of the lead frame is oxidized or sulfurized by oxygen, moisture and the like penetrated from the opening, the light reflection efficiency of the lead frame decreases. Thus, if the lead frame is stripped from the transparent resin body, the characteristics and reliability of the LED package are degraded.

Thus, in the LED package 1 according to this embodiment, the transparent resin body 17 covers parts of the lower surface and most of the edge surface of the lead frames 11 and 12, thereby retaining the peripheral portion of the lead frames 11 and 12. Hence, the retainability of the lead frames 11 and 12 can be enhanced while the lower surface of the protrusions 11g and 12g of the lead frames 11 and 12 is exposed from the transparent resin body 17 to realize external electrode pads. That is, the protrusions 11g and 12g are formed at the X direction center of the base portions 11a and 12a so that notches extending in the Y direction are realized at both X direction ends of the lower surface of the base portions 11a and 12a. By penetration of the transparent resin body 17 into this notch, the lead frames 11 and 12 can be robustly retained. This makes the lead frames 11 and 12 more resistant to being stripped from the transparent resin body 17 at the time of dicing. Moreover, this can prevent that lead frames 11 and 12 detach from the transparent resin body 17 by temperature stress in using the LED package 1.

Furthermore, in this embodiment, the extending portions extend from the base portions 11a and 12a of the lead frames 11 and 12. This can prevent the base portion itself from being exposed on the side surface of the transparent resin body 17 and reduce the exposed area of the lead frames 11 and 12. Moreover, the contact area between lead frames 11 and 12 and the transparent resin body 17 can be made to increase. Consequently, it can prevent the lead frames 11 and 12 from being stripped from the transparent resin body 17. Furthermore, it can also suppress corrosion of the lead frames 11 and 12.

Viewing this effect from the standpoint of the manufacturing method, as shown in FIG. 9B, the openings 23a and the bridges 23b and 23c are provided in the lead frame sheet 23 so as to be interposed in the dicing region D, thereby reducing the metal portion interposed in the dicing region D. This facilitates dicing, and can suppress attrition of the dicing blade. Furthermore, in this embodiment, four extending portions extend in three directions from each of the lead frames 11 and 12. Thus, in the process of mounting the LED chip 14 shown in FIG. 6C, the lead frame 11 is reliably supported from three directions by the lead frames 11 and 12 in the neighboring element regions P, thereby achieving high mountability. Likewise, also in the wire bonding process shown in FIG. 6D, the wire bonding position is reliably supported from three directions. Hence, for instance, ultrasonic waves applied in ultrasonic bonding are less likely to escape, and the wire can be favorably bonded to the lead frame and the LED chip.

In particular, in this embodiment, the wire bonding position is located inside the polygonal region connecting between the roots of two extending portions, or inside the polygonal region connecting among the roots of three extending portions. Hence, the wire bonding position can be robustly supported. That is, the bonding position X1 where the wire 15 is bonded to the lead frame 11 is located inside the region R1 and inside the region R2, and the bonding position X2 where the wire 16 is bonded to the lead frame 12 is located inside the region R3 and inside the region R4. Hence, the bonding positions X1 and X2 can be stably supported. This improves wire bonding performance at the bonding positions X1 and X2.

This effect can be generally expressed as follows. The wire bonding position is preferably located inside at least one polygonal region connecting between the roots of a plurality of extending portions residing on different sides of the base portion, and more preferably located inside an overlapping portion of a plurality of the regions. On the other hand, the wire connecting position is preferably located in the region which is not half-etched, i.e., the region where a protrusion is formed on its lower surface. That is, it is particularly preferable that the wire bonding position be located in an overlapping region of a plurality of the polygonal regions where the protrusion is formed on its lower surface. In this embodiment, the bonding position X1 is located inside the overlapping region of the region R1 and the region R2 where the protrusion 11g is formed on its lower surface, and the bonding position X2 is located inside the overlapping region of the region R3 and the region R4 where the protrusion 12g is formed on its lower surface. This particularly improves the wire bonding performance.

Furthermore, in the LED package 1 according to this embodiment, the shortest distance W from the edge surface of the base portions 11a and 12a to the side surface of the transparent resin body 17 is 50% or more of the maximum thickness t of the lead frames 11 and 12. Thus, in the transparent resin body 17, the portion located around the base portions 11a and 12a has a certain thickness in the X direction or Y direction, thereby ensuring the strength of this portion. Consequently, this can reliably prevent this portion from dropping off at the time of dicing.

In the following, this effect is described with reference to specific experimental data.

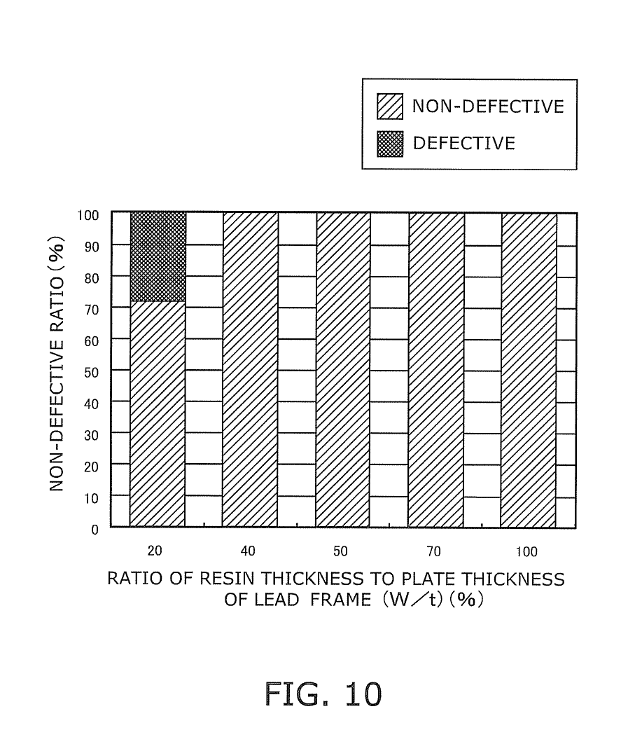

FIG. 10 is a graph illustrating the influence which the ratio of resin thickness W to the plate thickness t of the lead frame exerts on the appearance of the LED package, where the value of the ratio W/t is taken on the horizontal axis, and the determination result of the appearance of the LED package after dicing is taken on the vertical axis.

The vertical axis of FIG. 10 represents the non-defective ratio obtained by evaluating the appearance of 100 LED packages manufactured.

As shown in FIG. 10, when the ratio W/t was 20%, drop-off of the transparent resin body 17 was observed in 28 out of the 100 LED packages, and they were determined as defective. In contrast, when the ratio W/t was 40%, 50%, 70%, and 100%, all the LED packages were determined as non-defective. Thus, the ratio W/t is preferably 40% or more. However, considering the dicing condition variation and the like, the ratio W/t is more preferably 50% or more. Here, by forming the transparent resin body 17 from a resin with high toughness, drop-off of the transparent resin body 17 can be prevented even for a lower value of the ratio W/t.

Moreover, in the LED package 1 according to this embodiment, the roughness of the upper and lower surface of the conductive sheet 21 is 1.20 or more. Hence, the roughness of the upper and lower surface of the lead frame sheet 23 is 1.20 or more. This increases adhesiveness between the lead frame sheet 23 and the transparent resin plate 29, and can prevent the transparent resin body 17 from being stripped from the lead frames 11 and 12 at the time of dicing. Furthermore, in the LED package 1 after completion, the upper surface 11h and lower surface 11f of the lead frame 11, and the upper surface 12h and lower surface 12f of the lead frame 12 have a roughness of 1.20 or more. This improves adhesiveness between the lead frames 11 and 12 and the transparent resin body 17. These improve the reliability of the LED package 1.

In the following, this effect is described with reference to specific experimental data.

A plurality of copper plates 21a were prepared, and the silver plating layer 21b was formed on the upper and lower surface of these copper plates 21a under different conditions. Thus, a plurality of conductive sheets 21 with different surface roughnesses were fabricated. Next, these conductive sheets were used to manufacture LED packages 1 by the aforementioned method. Then, the reliability of these LED packages 1 was evaluated by an accelerated test. The evaluation result is shown in TABLE 1.

TABLE 1

| Roughness | Reliability |
|---|---|
| of lead frame | of LED package |
| 1.05 | X |
| 1.10 | Δ |
| 1.15 | Δ |
| 1.20 | ◯ |
| 1.25 | ◯ |

The lead frame having a roughness of 1.05 shown in TABLE 1 was obtained by forming the silver plating layer 21b under the normal plating condition. On the other hand, the lead frames having a roughness of 1.10 or more were obtained by forming the silver plating layer 21b under the plating condition of increasing the roughness. Here, as described earlier, the roughness of a completely flat hypothetical surface is 1.

As shown in TABLE 1, as the roughness of the upper and lower surface of the lead frames 11 and 12 becomes higher, the adhesiveness between the lead frame and the transparent resin body is higher, and the reliability of the LED package is higher. Specifically, for a roughness of 1.05, the reliability of the LED package was poor (X). However, for a roughness of 1.10 or 1.15, the reliability of the LED package was substantially favorable (A), and for a roughness of 1.20 or 1.25, the reliability of the LED package was favorable (O). Hence, the roughness of the upper and lower surface of the lead frames 11 and 12, i.e., the roughness of the upper and lower surface of the conductive sheet 21, is preferably 1.20 or more. It is noted that because the reliability evaluation result shown in TABLE 1 is the result of the accelerated test, reliability at a level of practically no problem can be achieved even for a roughness of less than 1.20.

Although this embodiment has been illustrated in the case where the roughness of both the upper surface and lower surface of the lead frame is 1.20 or more, a certain effect is achieved also when the roughness of only one of the surfaces, e.g. the upper surface, is 1.20 or more. In this case, for instance, the roughness can be made different between the upper surface and lower surface of the conductive sheet 21 by forming the silver plating layer 21b under different conditions for the upper surface and lower surface of the copper plate 21a.

Moreover, in this embodiment, a large number, e.g. approximately several thousands, of LED packages 1 can be collectively manufactured from one conductive sheet 21. Thus, the manufacturing cost per LED package can be reduced. Furthermore, because no enclosure is provided, the number of parts and the number of processes are smaller, achieving low cost.

Moreover, in this embodiment, the lead frame sheet 23 is formed by wet etching. Thus, in manufacturing an LED package with a new layout, it is only necessary to prepare a mask original plate. Thus, as compared with the case of forming the lead frame sheet 23 by press molding and the like, the initial cost can be suppressed at low level.

Moreover, in this embodiment, in the dicing process shown in FIG. 8B, dicing is performed from the lead frame sheet 23 side. Thus, the metal material forming the cut end of the lead frames 11 and 12 extends to the +Z direction on the side surface of the transparent resin body 17. This avoids burring which would occur if this metal material extends to the −Z direction on the side surface of the transparent resin body 17 and protrudes from the lower surface of the LED package 1. Hence, when the LED package 1 is mounted, no mounting failure occurs due to burring.

Moreover, the LED package 1 according to this embodiment is not provided with an enclosure made of a white resin. Hence, there is no degradation of the enclosure by absorbing light and heat generated from the LED chip 14. In particular, while degradation is likely to proceed in the case where the enclosure is formed from a polyamide-based thermoplastic resin, there is no such risk in this embodiment. Thus, the LED package 1 according to this embodiment has high durability. Hence, the LED package 1 according to this embodiment has long lifetime and high reliability, and is applicable to a wide variety of purposes.

Moreover, the LED package 1 according to this embodiment is not provided with an enclosure covering the side surface of the transparent resin body 17. Hence, light is emitted toward a wide angle. Thus, the LED package 1 according to this embodiment is advantageous for applications requiring light emission with a wide angle, such as lighting and backlights of liquid crystal televisions.

Moreover, in the LED package 1 according to this embodiment, the transparent resin body 17 is formed from silicone resin. Because silicone resin has high durability against light and heat, the durability of the LED package 1 is improved also for this reason.

Moreover, in the LED package 1 according to this embodiment, a silver plating layer is formed on the upper surface and lower surface of the lead frames 11 and 12. Because the silver plating layer has high light reflectance, the LED package 1 according to this embodiment has high light extraction efficiency.

Next, a variation of this embodiment is described.

This variation is a variation of the method for forming the lead frame sheet.

More specifically, this variation is different from the above first embodiment in the method for forming the lead frame sheet shown in FIG. 4A.

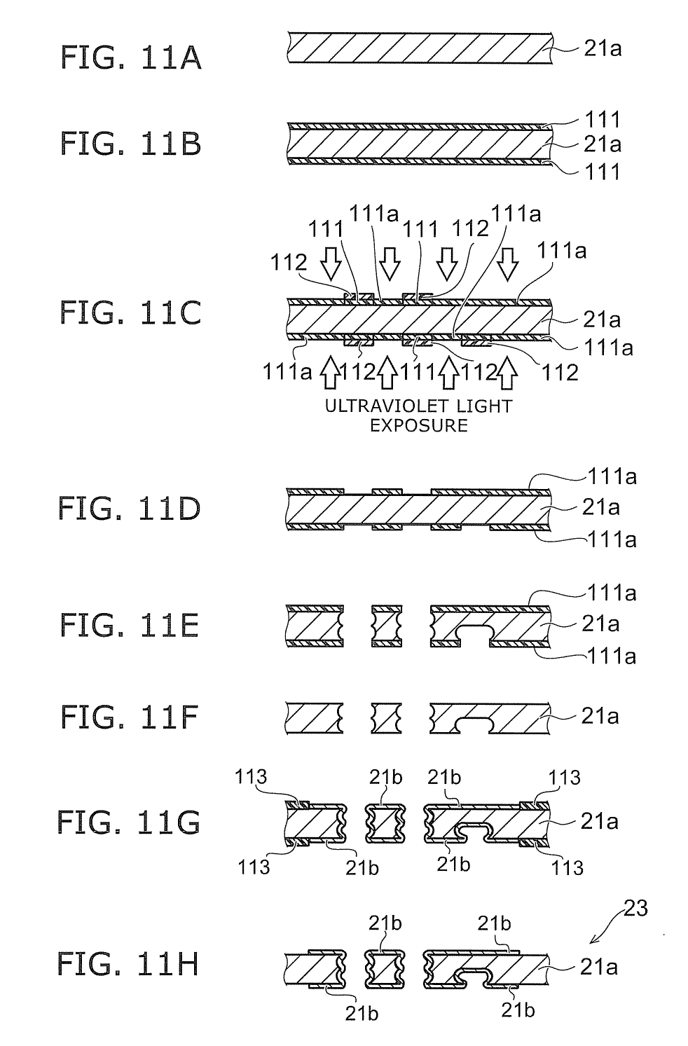

FIGS. 11A to 11H are process sectional views illustrating the method for forming the lead frame sheet in this variation.

First, as shown in FIG. 11A, the copper plate 21a is prepared and cleaned. Next, as shown in FIG. 11B, resist coating is performed on both surfaces of the copper plate 21a, which is then dried to form a resist film 111. Next, as shown in FIG. 11C, a mask pattern 112 is placed on the resist film 111 and exposed to ultraviolet radiation. Thus, the light-exposed portion of the resist film 111 is cured to form a resist mask 111a. Next, as shown in FIG. 11D, development is performed, and the uncured portion of the resist film 111 is washed away. Thus, the resist pattern 111a is left on the upper and lower surface of the copper plate 21a. Next, as shown in FIG. 11E, the resist pattern 111a is used as a mask to perform etching to remove the exposed portion of the copper plate 21a from both surfaces. At this time, the etching depth is set to approximately half the plate thickness of the copper plate 21a. Thus, the region etched only from one side is half-etched, and the region etched from both sides is penetrated. Next, as shown in FIG. 11F, the resist pattern 111a is removed. Next, as shown in FIG. 11G, the end of the copper plate 21a is covered with a mask 113, and plating is performed. Thus, the silver plating layer 21b is formed on the surface of the portion except the end of the copper plate 21a. Next, as shown in FIG. 11H, the mask 113 is removed by cleaning. Subsequently, inspection is performed. Thus, the lead frame sheet 23 is fabricated. The configuration, manufacturing method, and function and effect of this variation other than the foregoing are similar to those of the above first embodiment.

Next, a second embodiment is described.

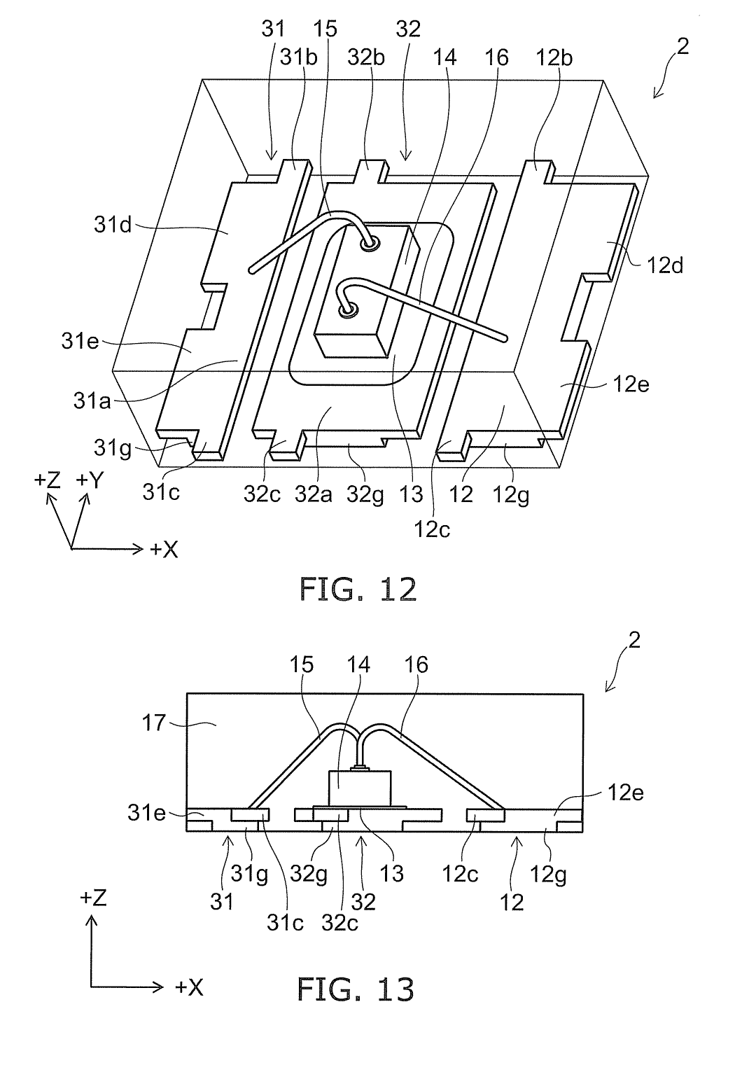

FIG. 12 is a perspective view illustrating an LED package according to this embodiment.

FIG. 13 is a side view illustrating the LED package according to this embodiment.

As shown in FIGS. 12 and 13, the LED package 2 according to this embodiment is different from the LED package 1 (see FIG. 1) according to the above first embodiment in that the lead frame 11 (see FIG. 1) is divided into two lead frames 31 and 32 in the X direction. The lead frame 32 is located between the lead frame 31 and the lead frame 12. In the lead frame 31, extending portions 31d and 31e corresponding to the extending portions 11d and lie (see FIG. 1) of the lead frame 11 are formed, and extending portions 31b and 31c extending from a base portion 31a to the +Y direction and −Y direction, respectively, are formed. The positions of the extending portions 31b and 31c in the X direction are the same. Furthermore, the wire 15 is bonded to the lead frame 31. On the other hand, in the lead frame 32, extending portions 32b and 32c corresponding to the extending portions 11b and 11c (see FIG. 1) of the lead frame 11 are formed, and the LED chip is mounted thereon via the die mount material 13. Furthermore, the protrusion corresponding to the protrusion 11g of the lead frame 11 is divided into protrusions 31g and 32g formed in the lead frames 31 and 32, respectively.

In this embodiment, the lead frames 31 and 12 function as external electrodes by external potential application. On the other hand, there is no need to apply a potential to the lead frame 32, and it can be used as a lead frame intended exclusively for a heat sink. Thus, in the case where a plurality of the LED packages 2 are mounted on one module, the lead frame 32 can be connected to a common heat sink. Here, the ground potential may be applied to the lead frame 32, or it may be placed in a floating state. When the LED package 2 is mounted on a mother board, the so-called Manhattan phenomenon can be suppressed by bonding a solder ball to each of the lead frames 31, 32, and 12. The Manhattan phenomenon is a phenomenon in which, when a device or the like is mounted on a substrate via a plurality of solder balls and the like, the device rises up due to the different melting timing of the solder balls in the reflow furnace and the surface tension of solder. This is a phenomenon causing mounting failure. According to this embodiment, the layout of the lead frame is symmetrized in the X direction, and the solder balls are densely placed in the X direction. Thus, the Manhattan phenomenon is unlikely to occur.

Furthermore, in this embodiment, the lead frame 31 is supported from three directions by the extending portions 31b-31e, hence improving the bonding performance of the wire 15. Likewise, the lead frame 12 is supported from three directions by the extending portions 12b-12e, hence improving the bonding performance of the wire 16.

The LED package 2 like this can be manufactured by a method similar to that of the above first embodiment by changing the basic pattern of each element region P of the lead frame sheet 23 in the process described above with reference to FIG. 6A. That is, the manufacturing method described in the above first embodiment can manufacture LED packages with various layouts simply by changing the pattern of the masks 22a and 22b. The configuration, manufacturing method, and function and effect of this embodiment other than the foregoing are similar to those of the above first embodiment.

Next, a third embodiment is described.

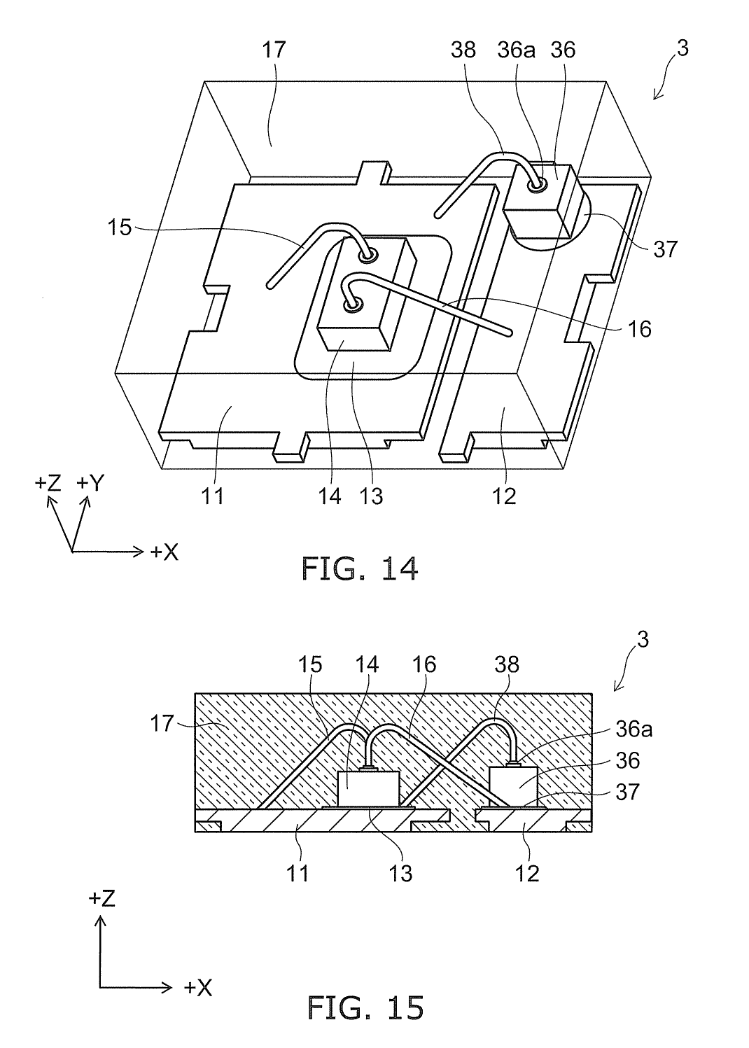

FIG. 14 is a perspective view illustrating an LED package according to this embodiment.

FIG. 15 is a sectional view illustrating the LED package according to this embodiment.

As shown in FIGS. 14 and 15, in addition to the configuration of the LED package 1 (see FIG. 1) according to the above first embodiment, the LED package 3 according to this embodiment includes a Zener diode chip 36, for instance, which is connected between the lead frame 11 and the lead frame 12. More specifically, a die mount material 37 made of a conductive material such as solder or silver paste is attached onto the upper surface of the lead frame 12, and the Zener diode chip 36 is provided thereon. Thus, the Zener diode chip 36 is mounted on the lead frame 12 via the die mount material 37, and the lower surface terminal (not shown) of the Zener diode chip 36 is connected to the lead frame 12 via the die mount material 37. Furthermore, an upper surface terminal 36a of the Zener diode chip 36 is connected to the lead frame 11 via a wire 38. That is, one end of the wire 38 is connected to the upper surface terminal 36a of the Zener diode chip 36, the wire 38 is drawn out from the terminal 36a to the +Z direction and bent toward the direction between the −Z direction and the −X direction, and the other end of the wire 38 is bonded to the upper surface of the lead frame 11.

Thus, in this embodiment, the Zener diode chip 36 can be connected parallel to the LED chip 14. Consequently, this improves ESD (electrostatic discharge) resistance. The configuration, manufacturing method, and function and effect of this embodiment other than the foregoing are similar to those of the above first embodiment.

Next, a fourth embodiment is described.

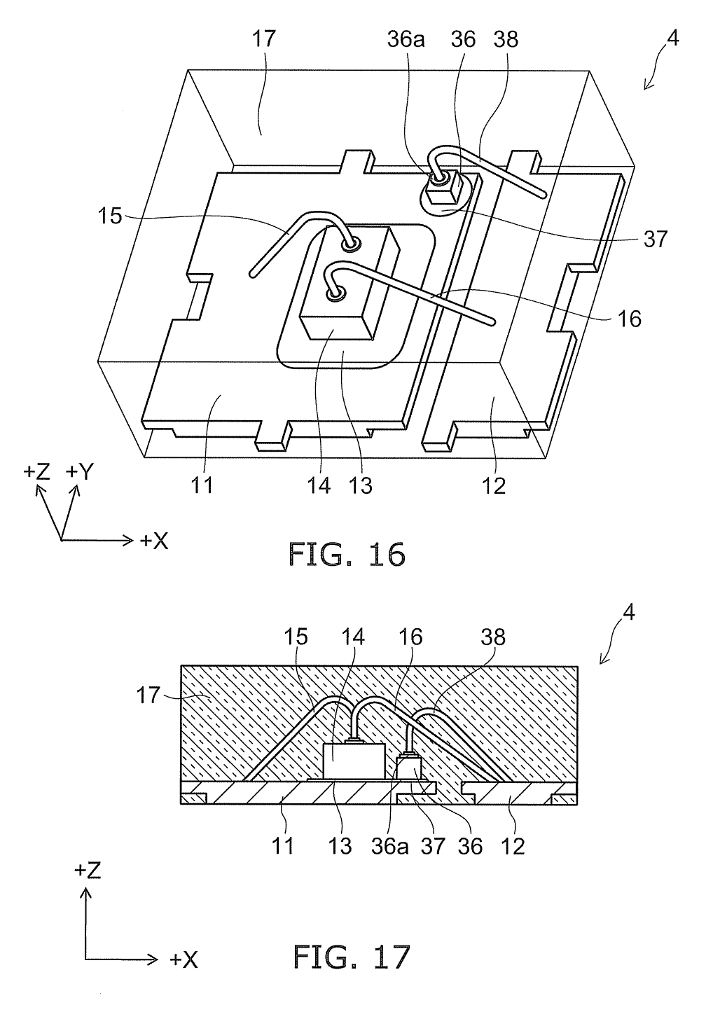

FIG. 16 is a perspective view illustrating an LED package according to this embodiment.

FIG. 17 is a sectional view illustrating the LED package according to this embodiment.

As shown in FIGS. 16 and 17, the LED package 4 according to this embodiment is different from the LED package 3 (see FIG. 14) according to the above third embodiment in that the Zener diode chip 36 is mounted on the lead frame 11. In this case, the lower surface terminal of the Zener diode chip 36 is connected to the lead frame 11 via the die mount material 37, and the upper surface terminal is connected to the lead frame 12 via the wire 38. The configuration, manufacturing method, and function and effect of this embodiment other than the foregoing are similar to those of the above third embodiment.

Next, a fifth embodiment is described.

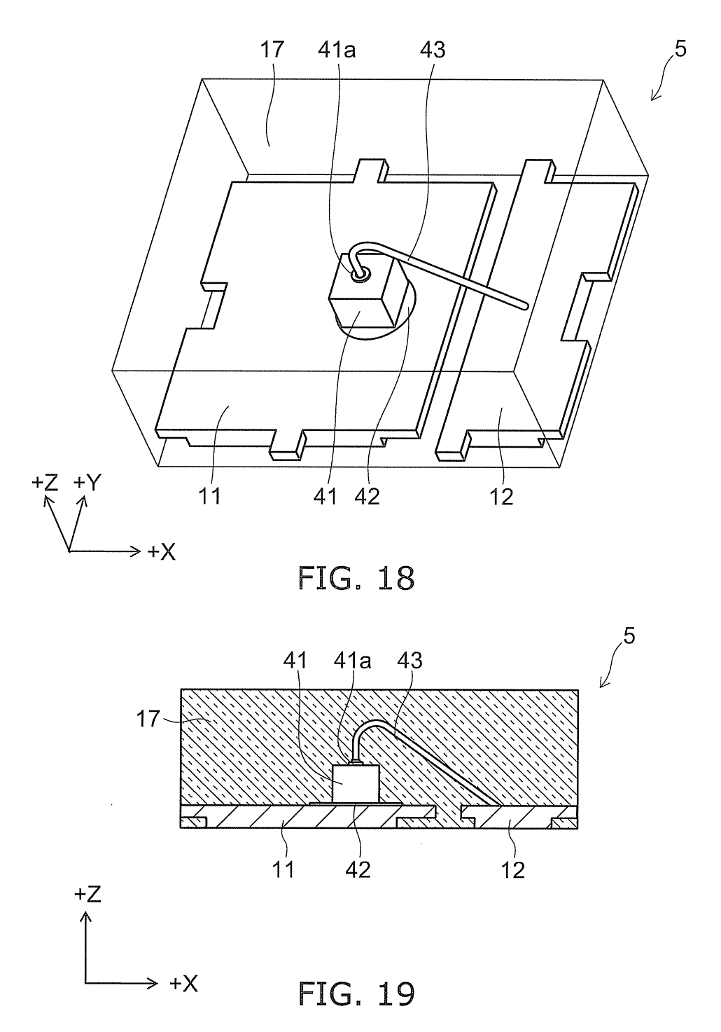

FIG. 18 is a perspective view illustrating an LED package according to this embodiment.

FIG. 19 is a sectional view illustrating the LED package according to this embodiment.

As shown in FIGS. 18 and 19, the LED package 5 according to this embodiment is different from the LED package 1 (see FIG. 1) according to the above first embodiment in including a vertically conducting LED chip 41 instead of the LED chip 14 having upper surface terminals. More specifically, in the LED package 5 according to this embodiment, a die mount material 42 made of a conductive material such as solder or silver paste is formed on the upper surface of the lead frame 11, and the LED chip 41 is mounted thereon via the die mount material 42. The lower surface terminal (not shown) of the LED chip 41 is connected to the lead frame 11 via the die mount material 42. On the other hand, the upper surface terminal 41a of the LED chip 41 is connected to the lead frame 12 via a wire 43.

In this embodiment, a vertically conducting LED chip 41 is adopted, and a single wire is used. This can reliably prevent contact between wires, and simplify the wire bonding process. The configuration, manufacturing method, and function and effect of this embodiment other than the foregoing are similar to those of the above first embodiment.

Next, a sixth embodiment is described.

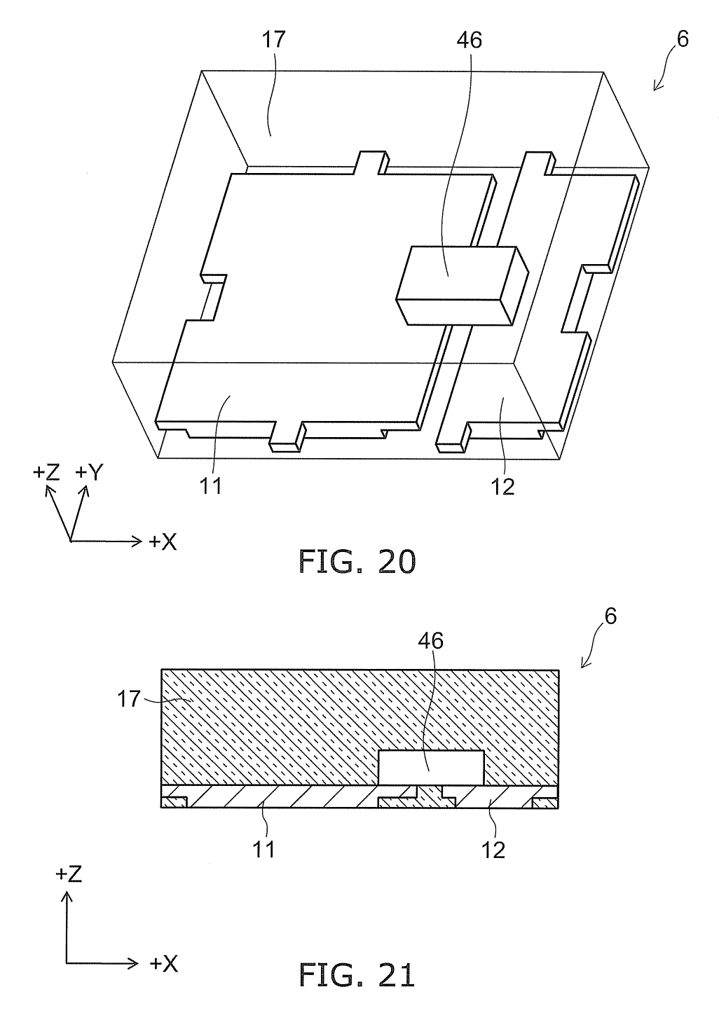

FIG. 20 is a perspective view illustrating an LED package according to this embodiment.

FIG. 21 is a sectional view illustrating the LED package according to this embodiment.

As shown in FIGS. 20 and 21, the LED package 6 according to this embodiment is different from the LED package 1 (see FIG. 1) according to the above first embodiment in including a flip-type LED chip 46 instead of the LED chip 14 having upper surface terminals. More specifically, in the LED package 6 according to this embodiment, two terminals are provided on the lower surface of the LED chip 46. Furthermore, the LED chip 46 is placed like a bridge so as to straddle between the lead frame 11 and the lead frame 12. One lower surface terminal of the LED chip 46 is connected to the lead frame 11, and the other lower surface terminal is connected to the lead frame 12.

In this embodiment, the flip-type LED chip 46 is adopted to eliminate wires. This can enhance the upward light extraction efficiency and omit the wire bonding process. Furthermore, it can also prevent wire breakage due to thermal stress of the transparent resin body 17. The configuration, manufacturing method, and function and effect of this embodiment other than the foregoing are similar to those of the above first embodiment.

Next, a seventh embodiment is described.

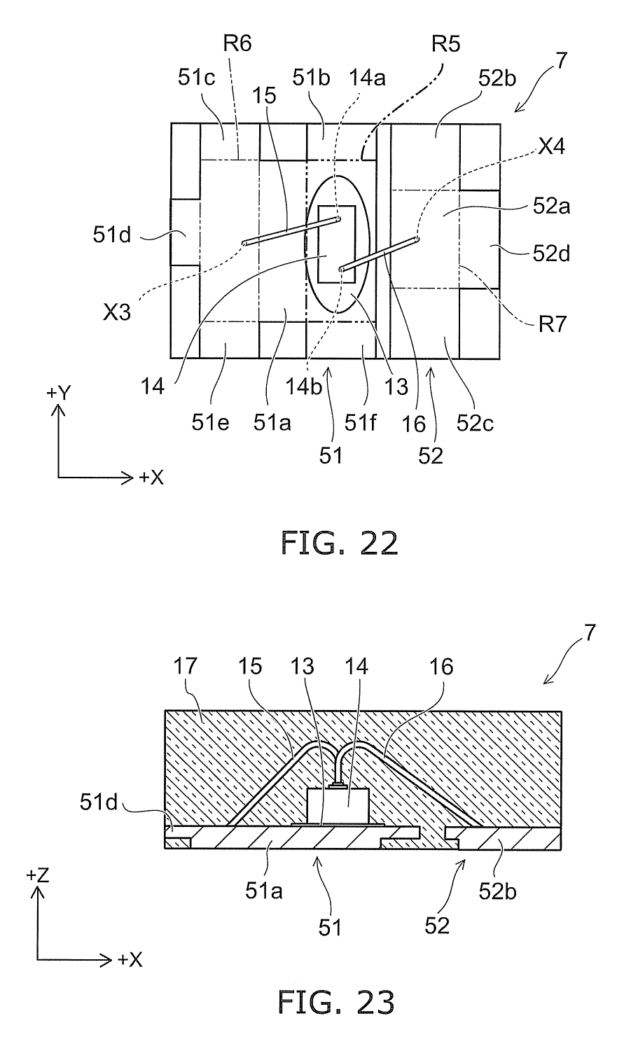

FIG. 22 is a plan view illustrating an LED package according to this embodiment.

FIG. 23 is a sectional view illustrating the LED package according to this embodiment.

As shown in FIGS. 22 and 23, the LED package 7 according to this embodiment includes lead frames 51 and 52. The lead frame 51 includes a base portion 51a, which is rectangular as viewed from the +Z direction. In the base portion 51a, extending portions 51b and 51c extend from the +X direction and −X direction end, respectively, of the +Y direction facing edge toward the +Y direction, a extending portion 51d extends from the Y direction center of the −X direction facing edge toward the −X direction, and extending portions 51e and 51f extend from the −X direction and +X direction end, respectively, of the −Y direction facing edge toward the −Y direction. Furthermore, the lead frame 52 includes a base portion 52a, which is rectangular as viewed from the +Z direction. In the base portion 52a, a extending portion 52b extends from the entire +Y direction facing edge toward the +Y direction, a extending portion 52c extends from the entire −Y direction facing edge toward the −Y direction, and a extending portion 52d extends from the entire +X direction facing edge toward the +X direction. Furthermore, an LED chip 14 is mounted on the main portion 51a of the lead frame 51 via the die mount material 13.

As viewed from the +Z direction, the bonding positions where the wires 15 and 16 are bonded to the LED chip 14, i.e., the positions of the terminals 14a and 14b, are located inside the polygonal region R5 connecting between the roots of the extending portion 51b and the extending portion 51f. Furthermore, the bonding position X3 where the wire 15 is bonded to the lead frame 51 is located inside the polygonal region R6 connecting between the roots of the extending portion 51c and the extending portion 51e. Moreover, the bonding position X4 where the wire 16 is bonded to the lead frame 52 is located inside the polygonal region R7 connecting between the roots of the extending portion 52b and the extending portion 52c.

According to this embodiment, as viewed from the +Z direction, the terminals 14a and 14b are located inside the region R5, the bonding position X3 is located inside the region R6, and the bonding position X4 is located inside the region R7, hence improving wire bonding performance at these positions. The configuration, manufacturing method, and function and effect of this embodiment other than the foregoing are similar to those of the above first embodiment.

Next, an eighth embodiment is described.

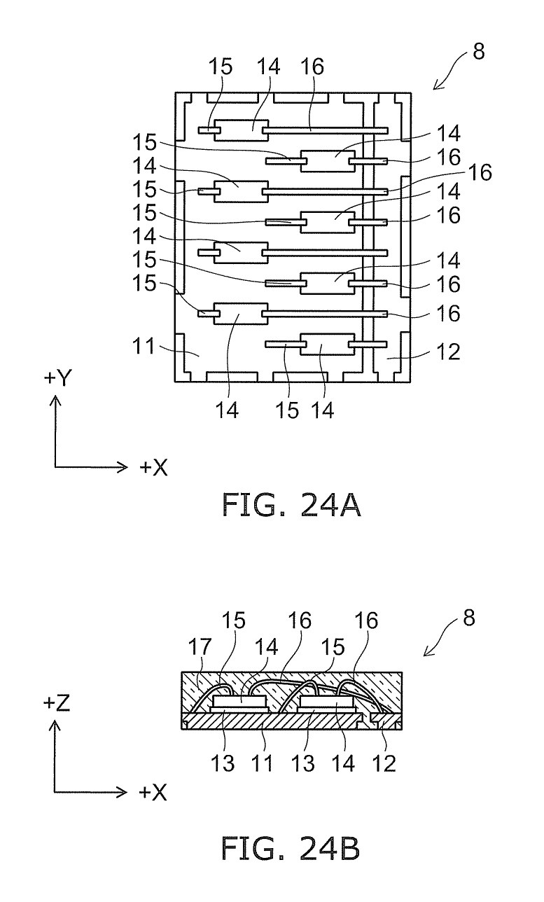

FIG. 24A is a plan view illustrating an LED package according to this embodiment, and FIG. 24B is a sectional view thereof.

As shown in FIGS. 24A and 24B, the LED package 8 according to this embodiment is different from the LED package 1 (see FIG. 1) according to the above first embodiment in including a plurality of, e.g. eight, LED chips 14. These eight LED chips 14 are chips emitting light of the same color and meeting the same specifications.

The eight LED chips 14 are all mounted on the lead frame 11. The terminal 14a (see FIG. 1) of each LED chip 14 is connected to the lead frame 11 via the wire 15, and the terminal 14b (see FIG. 1) of each LED chip 14 is connected to the lead frame 12 via the wire 16. Thus, the eight LED chips 14 are connected parallel to each other between the lead frame 11 and the lead frame 12. Furthermore, the eight LED chips 14, two along the X direction and four along the Y direction, are not arranged in a matrix but in a zigzag alignment. That is, the phase of arrangement of the column consisting of four LED chips 14 located on the +X direction side and arranged along the Y direction is shifted by a half pitch with respect to the phase of arrangement of the column consisting of four LED chips 14 located on the −X direction side and arranged along the Y direction.

According to this embodiment, a larger amount of light can be obtained by installing a plurality of LED chips 14 on one LED package 8. Furthermore, by arranging the LED chips 14 in a zigzag alignment, the LED package 8 can be downsized while maintaining the shortest distance between the LED chips 14 at a certain value or more. Maintaining the shortest distance between the LED chips 14 at a certain value or more increases the probability that the light emitted from one LED chip 14 is absorbed by a phosphor before reaching the adjacent LED chip 14, and improves the light extraction efficiency. Furthermore, heat emitted from one LED chip 14 is less likely to be absorbed by the adjacent LED chip 14, which can suppress the decrease of light emission efficiency due to the temperature increase of the LED chips 14. The configuration, manufacturing method, and function and effect of this embodiment other than the foregoing are similar to those of the above first embodiment.

Next, a first variation of the eighth embodiment is described.

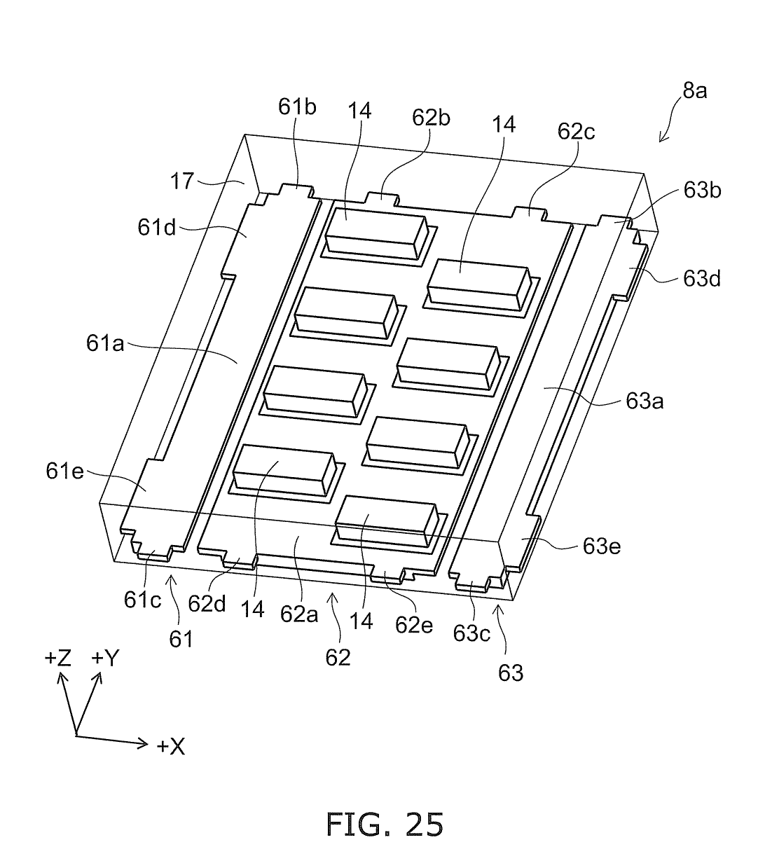

FIG. 25 is a perspective view illustrating an LED package according to this variation.

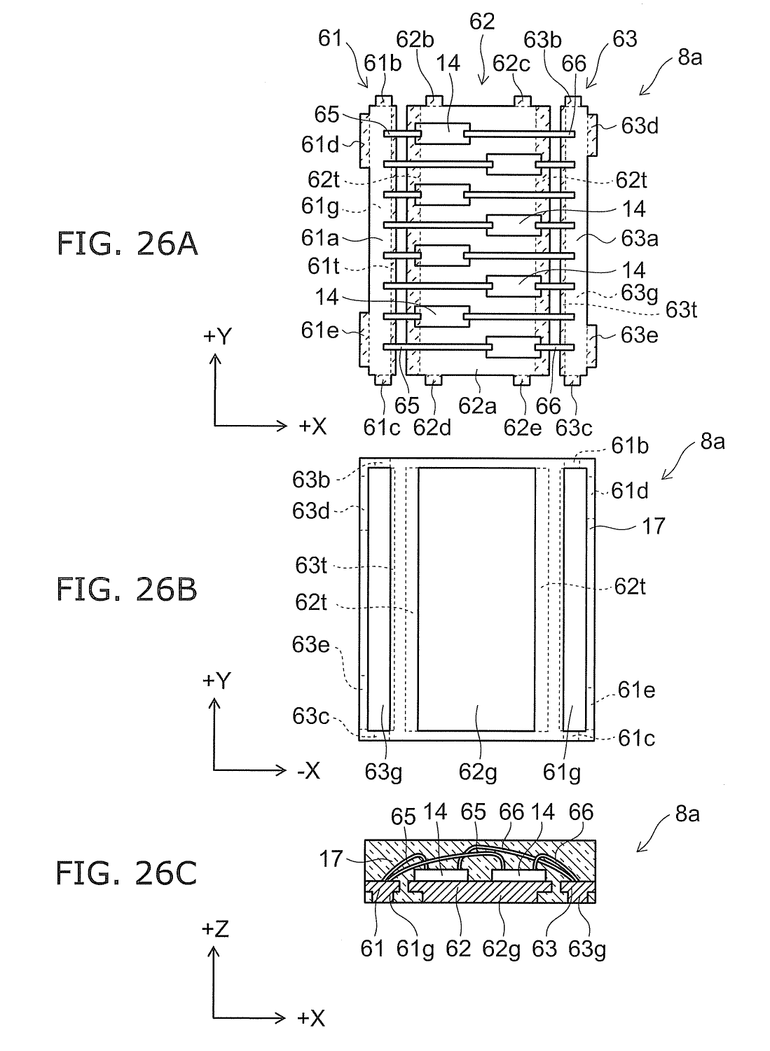

FIG. 26A is a plan view illustrating lead frames, LED chips, and wires of the LED package according to this variation, FIG. 26B is a bottom view illustrating the LED package, and FIG. 26C is a sectional view illustrating the LED package.

It is noted that wires are not shown in FIG. 25.

As shown in FIGS. 25 and 26A to 26C, this variation is an example of combining the second embodiment and the eighth embodiment described above. More specifically, the LED package 8a according to this variation includes three lead frames 61, 62, and 63 apart from each other. In the lead frame 61, from a strip-shaped base portion 61a with the longitudinal direction directed in the Y direction, a extending portion 61b extends to the +Y direction, a extending portion 61c extends to the −Y direction, and two extending portions 61d and 61e extend to the −X direction. In the lead frame 62, from a strip-shaped base portion 62a with the longitudinal direction directed in the Y direction, two extending portions 62b and 62c extend to the +Y direction, and two extending portions 62d and 62e extend to the −Y direction. The shape of the lead frame 63 is substantially the shape obtained by inverting the lead frame 61 in the X direction, but extending portions 63d and 63e are narrower than the extending portions 61d and 61e.

The LED package 8a includes a plurality of, e.g. eight, LED chips 14. The arrangement of the LED chips 14 in this variation is similar to that of the above eighth embodiment. More specifically, the LED chips 14 are arranged in two columns, each including four chips along the Y direction. The phase of arrangement of the column on the +X direction side is shifted by a half pitch with respect to that on the −X direction side, and the columns are in a zigzag alignment. Each LED chip 14 is mounted on the lead frame 62 via a die mount material (not shown), the terminal 14a (see FIG. 1) is connected to the lead frame 61 via a wire 65, and the terminal 14b (see FIG. 1) is connected to the lead frame 63 via a wire 66. Furthermore, the lower surface of protrusions 61g, 62g, and 63g of the lead frames 61, 62, and 63, respectively, is exposed on the lower surface of the transparent resin body 17. In contrast, the lower surface of thin plate portions 61t, 62t, and 63t of the lead frames 61, 62, and 63, respectively, is covered with the transparent resin body 17. In FIG. 26A, the relatively thin portions in the lead frames 61, 62, and 63, i.e., the thin plate portions and the extending portions, are hatched with dashed lines

Also in this variation, like the above eighth embodiment, a larger amount of light can be obtained by providing eight LED chips 14. Furthermore, like the above second embodiment, by providing three lead frames, electrically independent heat sinks are realized, and the Manhattan phenomenon can be suppressed. Moreover, by arranging the LED chips 14 in a zigzag alignment, the LED package 8a can be downsized while ensuring the emission efficiency and extraction efficiency of light.

In the following, this effect is described with reference to a specific numerical example. For instance, the LED chip 14 has a length of 0.60 mm in the X direction and 0.24 mm in the Y direction. The X direction distance between the LED chips 14 in the projection of the eight LED chips 14 on the XZ plane is 0.20 mm, and the Y direction distance between the LED chips 14 in the projection on the YZ plane is 0.10 mm. Then, if the LED chips 14 are in a zigzag alignment, the eight LED chips 14 can be placed on a rectangular base portion 42a having a length of 1.6 mm in the X direction and 3.0 mm in the Y direction. In this case, the shortest distance between the LED chips 14 is √(0.10²+0.20²)≈0.22 mm. The configuration, manufacturing method, and function and effect of this variation other than the foregoing are similar to those of the above second embodiment.

Next, a second variation of the eighth embodiment is described.

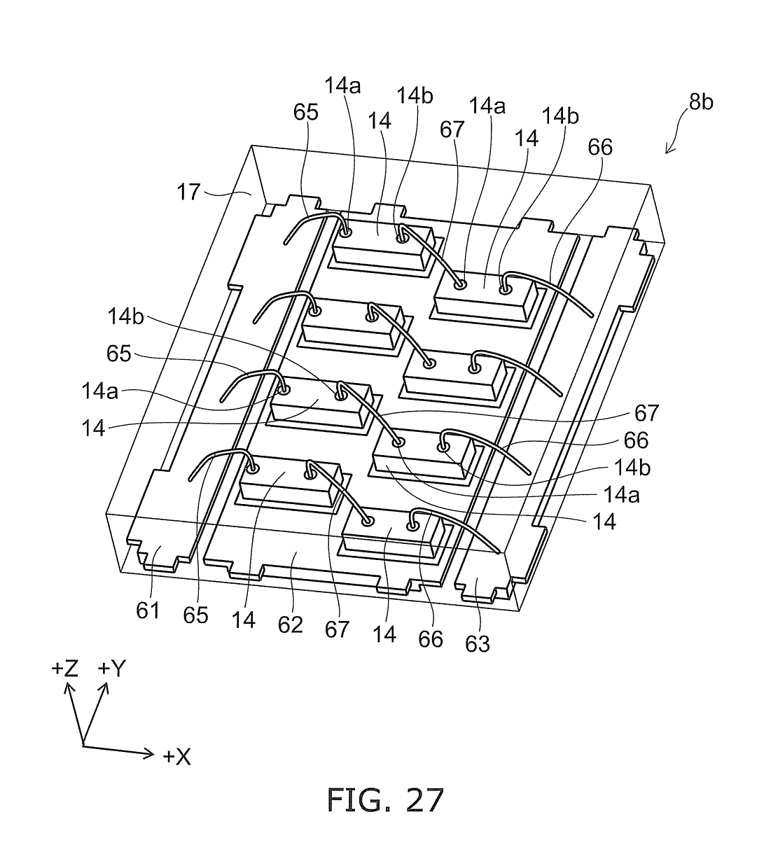

FIG. 27 is a perspective view illustrating an LED package according to this variation.

As shown in FIG. 27, the LED package 8b according to this variation is different from the LED package 8a (see FIG. 25) according to the above first variation of the eighth embodiment in that the terminal 14a of each LED chip 14 belonging to the column on the +X direction side is connected to the terminal 14b of the corresponding LED chip 14 belonging to the column on the −X direction side via a corresponding wire 67. Thus, four circuits each including two LED chips 14 connected in series are connected in parallel between the lead frame 11 and the lead frame 12. The configuration, manufacturing method, and function and effect of this variation other than the foregoing are similar to those of the above first variation of the eighth embodiment.

Next, a third variation of the eighth embodiment is described.

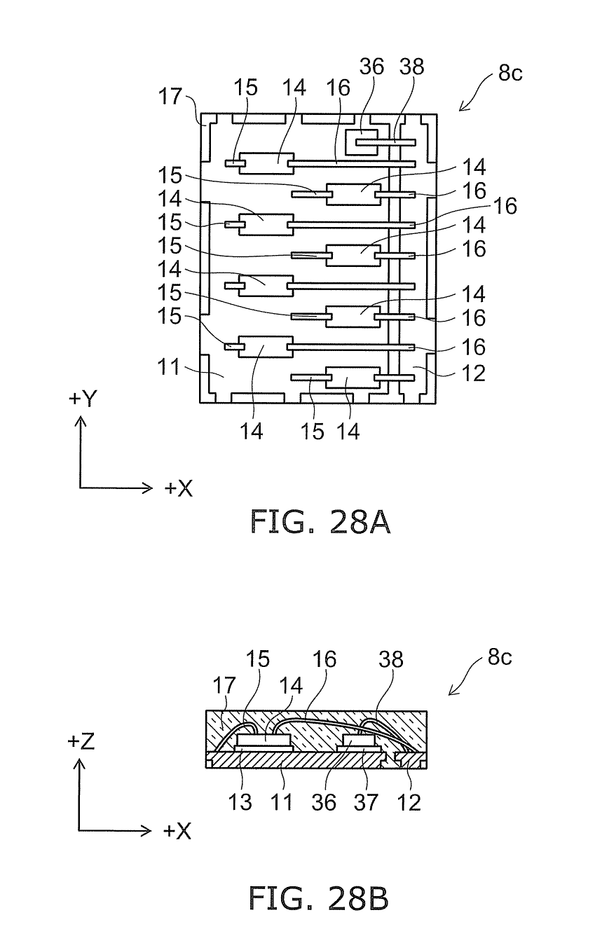

FIG. 28A is a plan view illustrating an LED package according to this variation, and FIG. 28B is a sectional view thereof.

As shown in FIGS. 28A and 28B, the LED package 8c according to this variation includes one Zener diode chip 36 in addition to the configuration of the LED package 8 (see FIG. 24) according to the above eighth embodiment. The Zener diode chip 36 is mounted on the lead frame 11 via the conductive die mount material 37. The lower surface terminal (not shown) of the Zener diode chip 36 is connected to the lead frame 11 via the die mount material 37, and the upper surface terminal is connected to the lead frame 12 via the wire 38. Thus, the Zener diode chip 36 is connected parallel to the eight LED chips between the lead frame 11 and the lead frame 12. According to this variation, ESD resistance can be improved by providing the Zener diode chip 36. The configuration, manufacturing method, and function and effect of this variation other than the foregoing are similar to those of the above eighth embodiment.

Next, a fourth variation of the eighth embodiment is described.

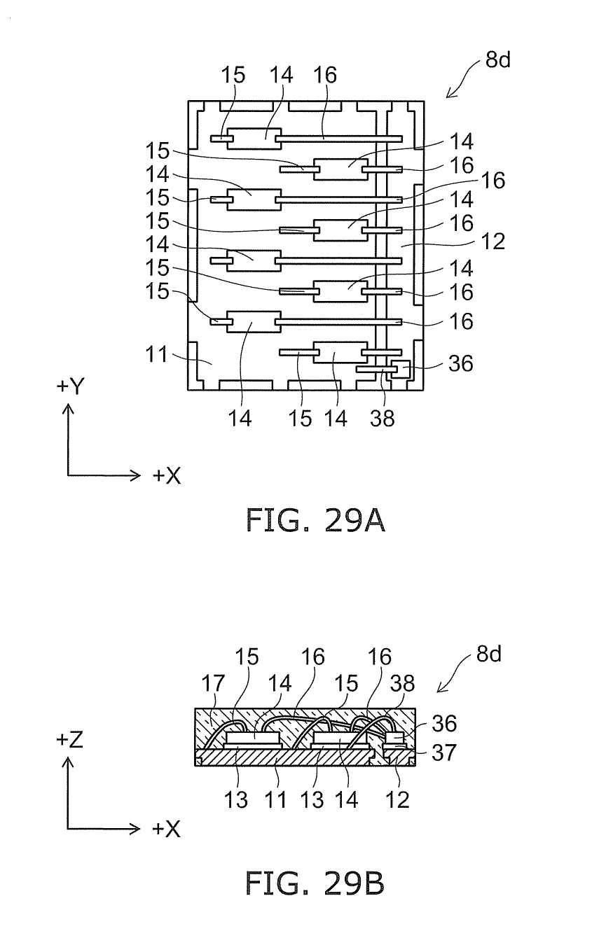

FIG. 29A is a plan view illustrating an LED package according to this variation, and FIG. 29B is a sectional view thereof.

As shown in FIGS. 29A and 29B, the LED package 8d according to this variation is different from the LED package 8c (see FIG. 28) according to the above third variation of the eighth embodiment in that the Zener diode chip 36 is mounted on the lead frame 12. The configuration, manufacturing method, and function and effect of this variation other than the foregoing are similar to those of the above third variation of the eighth embodiment.

Next, a fifth variation of the eighth embodiment is described.

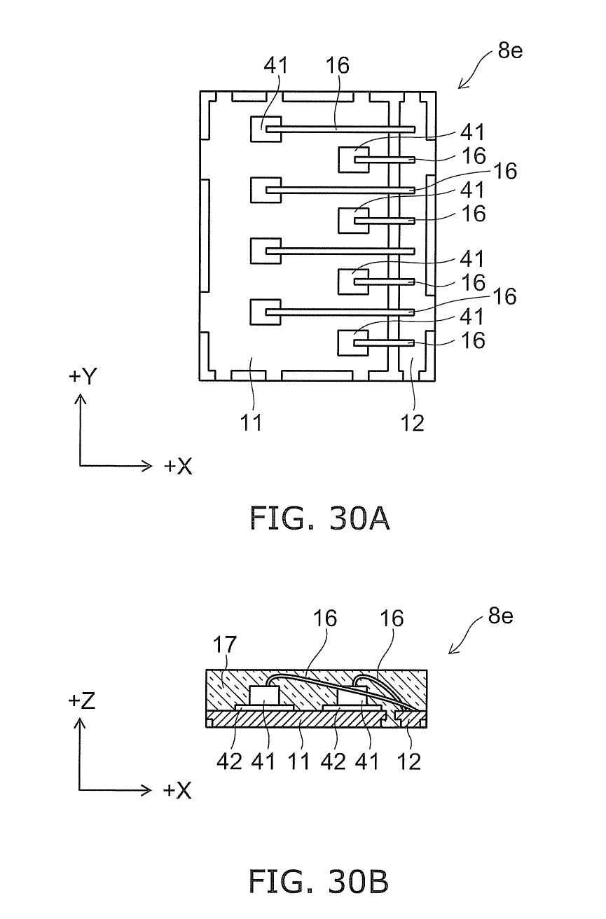

FIG. 30A is a plan view illustrating an LED package according to this variation, and FIG. 30B is a sectional view thereof.

As shown in FIGS. 30A and 30B, this variation is an example of combining the fifth embodiment and the eighth embodiment described above. More specifically, the LED package 8e according to this variation is different from the LED package 8 (see FIG. 24) according to the above eighth embodiment in including eight vertically conducting LED chips 41 instead of the eight LED chips 14 having upper surface terminals. Furthermore, like the fifth embodiment, the lower surface terminal (not shown) of each LED chip 41 is connected to the lead frame 11 via the conductive die mount material 42, and the upper surface terminal 41a of each LED chip 41 is connected to the lead frame 12 via the wire 16. The configuration, manufacturing method, and function and effect of this variation other than the foregoing are similar to those of the above fifth and eighth embodiment.

Next, a sixth variation of the eighth embodiment is described.

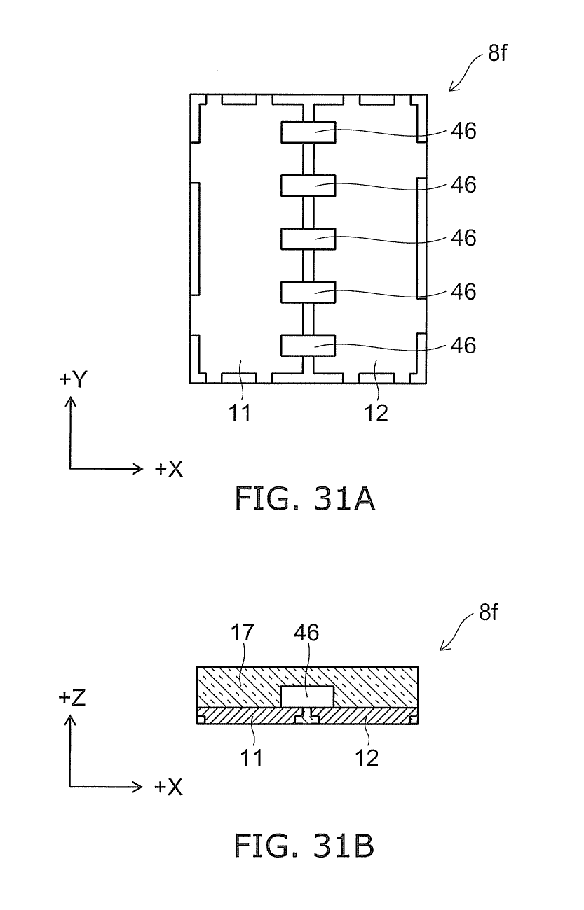

FIG. 31A is a plan view illustrating an LED package according to this variation, and FIG. 31B is a sectional view thereof.

As shown in FIGS. 31A and 31B, this variation is an example of combining the sixth embodiment and the eighth embodiment described above. More specifically, the LED package 8f according to this variation is different from the LED package 8 (see FIG. 24) according to the above eighth embodiment in including five flip-type LED chips 46 instead of the eight LED chips 14 having upper surface terminals. Furthermore, like the sixth embodiment, each LED chip 46 is placed like a bridge so as to straddle between the lead frame 11 and the lead frame 12, with one lower surface terminal connected to the lead frame 11 and the other lower surface terminal connected to the lead frame 12. Thus, the five LED chips 46 are connected parallel to each other between the lead frame 11 and the lead frame 12. The configuration, manufacturing method, and function and effect of this variation other than the foregoing are similar to those of the above sixth and eighth embodiment.

Next, a seventh variation of the eighth embodiment is described.

This variation is an example of the manufacturing method for the above eighth embodiment and the variations thereof.

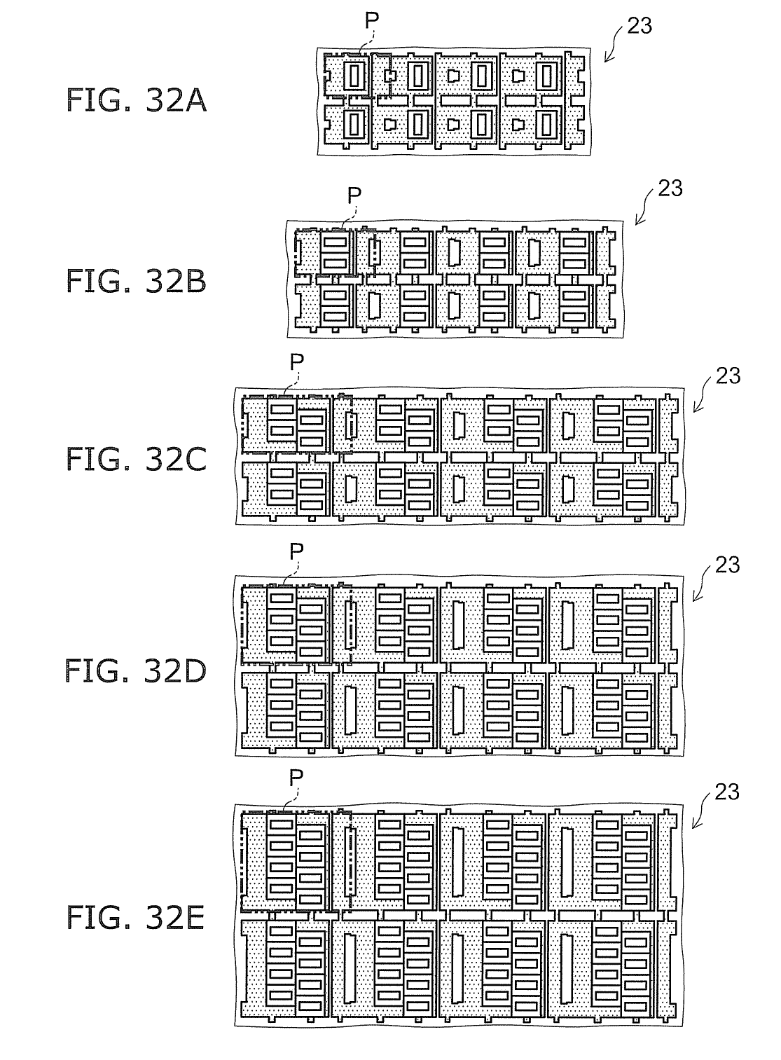

FIGS. 32A to 32E are plan views illustrating the element region of the lead frame sheet used in this variation, where FIG. 32A shows the case of installing one LED chip on one LED package, FIG. 32B shows the case of installing two LED chips, FIG. 32C shows the case of installing four LED chips, FIG. 32D shows the case of installing six LED chips, and FIG. 32E shows the case of installing eight LED chips.

Here, FIGS. 32A to 32E are depicted in the same scale. Furthermore, only one element region P is shown in each figure, but actually, numerous element regions P are arranged in a matrix. Moreover, the dicing region D is not shown.

As shown in FIGS. 32A to 32E, as the number of LED chips mounted on one LED package becomes larger, the area of one element region P increases, and the number of element regions P included in one block B decreases. However, even if the number of LED chips changes, the basic structure of the lead frame sheet 23, such as the size of the lead frame sheet 23 and the arrangement of blocks B, is the same, the method for forming the lead frame sheet 23 is also the same, and the method for manufacturing an LED package using the lead frame sheet 23 is also the same, except that only the layout in the block B changes.

Thus, according to this variation, the LED package according to the above eighth embodiment and the variations thereof can be selectively formed simply by changing the layout in each block B in the lead frame sheet 23. Here, the number of LED chips mounted on one LED package is arbitrary, and may be seven, or nine or more, for instance.

Next, a ninth embodiment is described.

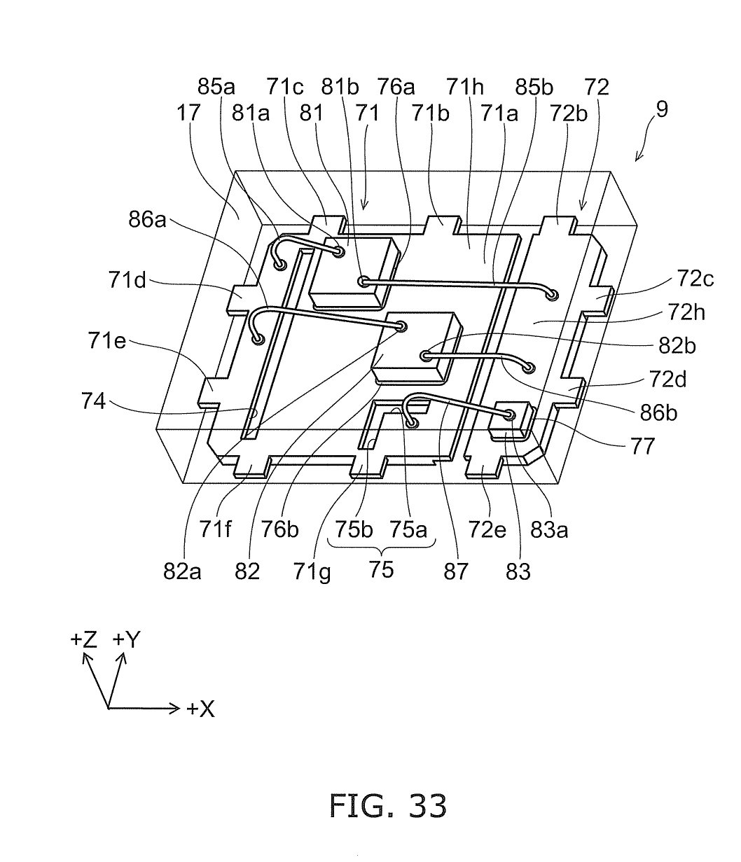

FIG. 33 is an upper perspective view illustrating an LED package according to this embodiment.

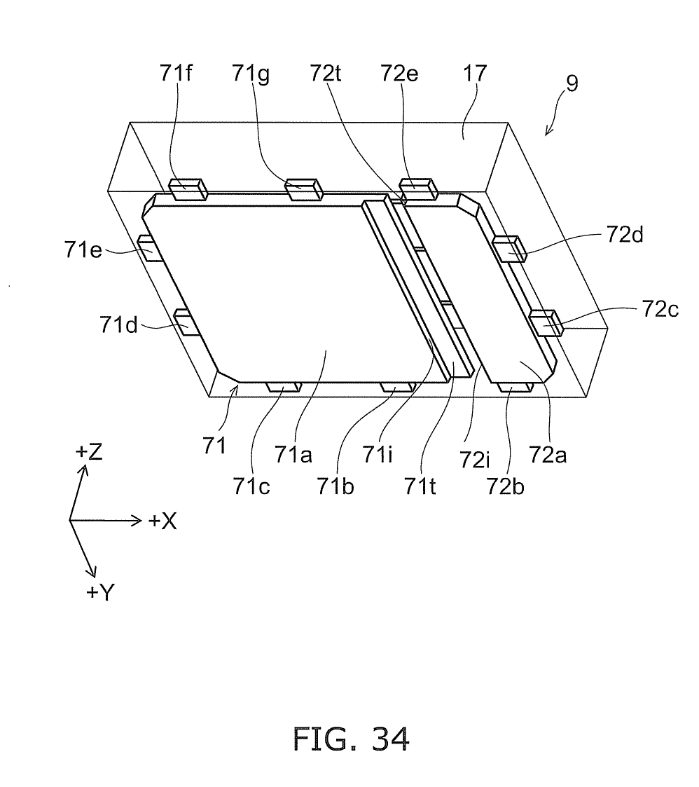

FIG. 34 is a lower perspective view illustrating the LED package according to this embodiment.

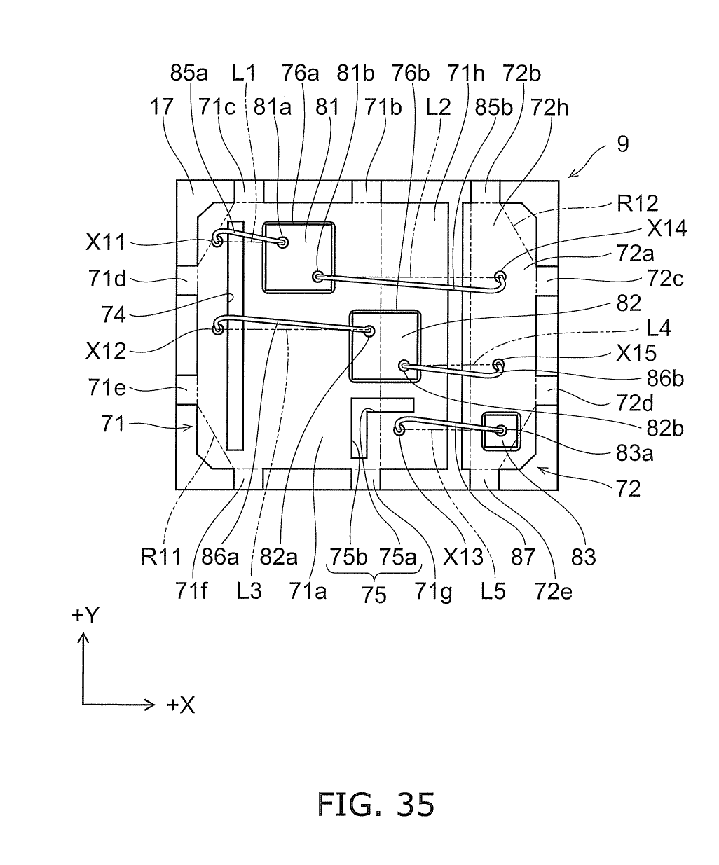

FIG. 35 is a top view illustrating the LED package according to this embodiment.

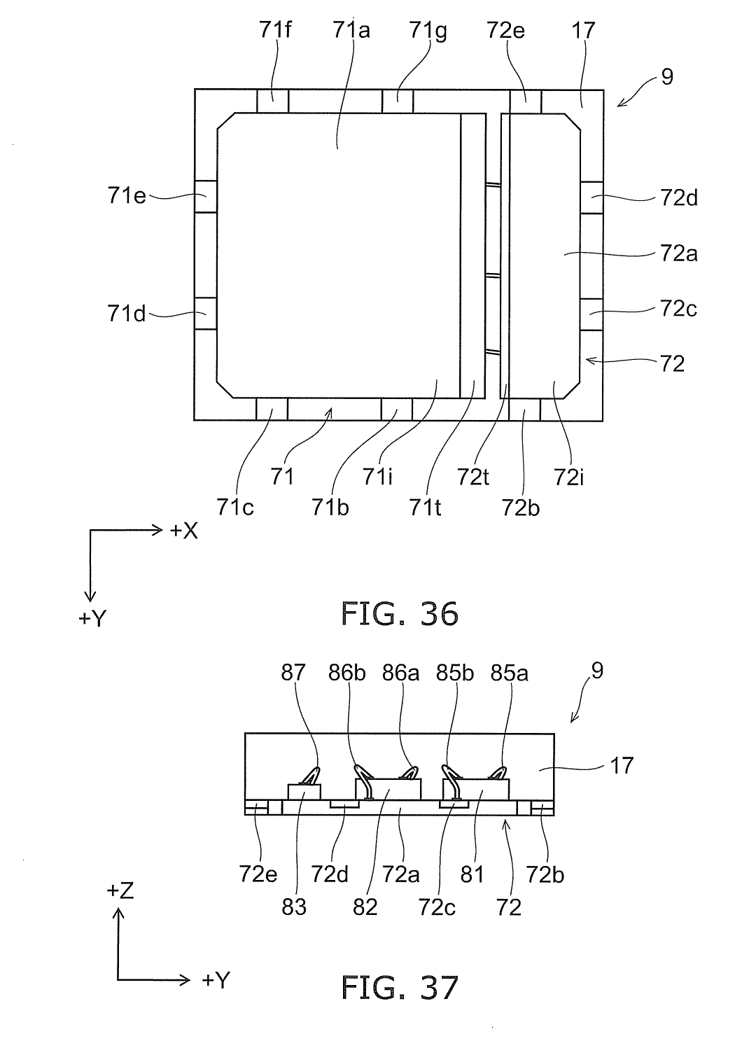

FIG. 36 is a bottom view illustrating the LED package according to this embodiment.

FIG. 37 is a side view viewed in an X direction illustrating the LED package according to the ninth embodiment.

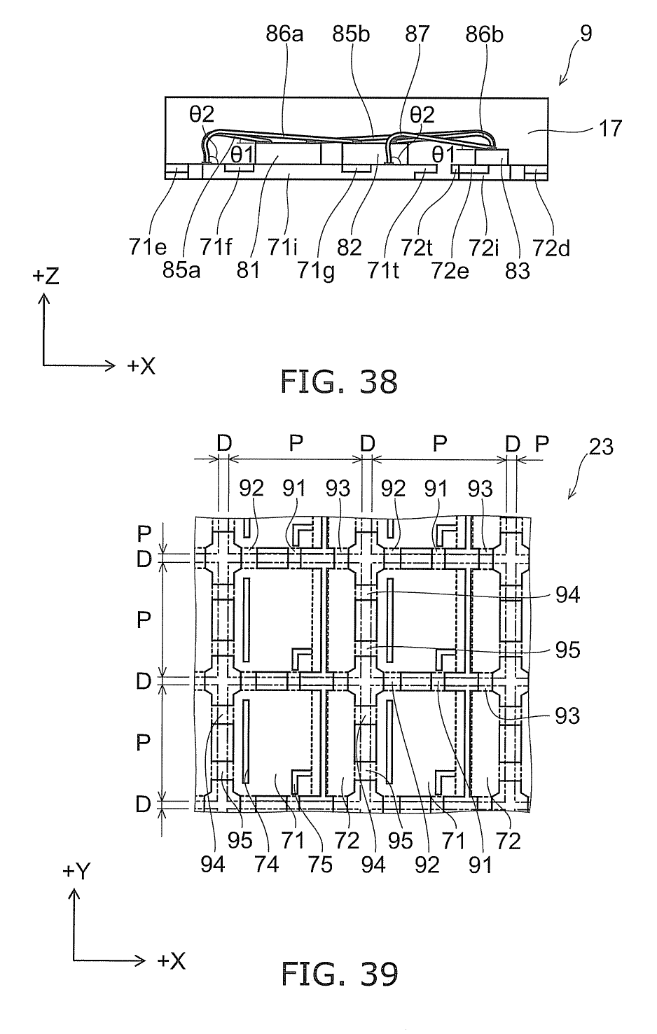

FIG. 38 is a side view viewed in a Y direction illustrating the LED package according to the ninth embodiment.

As shown in FIGS. 33 to 38, an LED package 9 according to this embodiment includes a pair of lead frames 71 and 72. The lead frames 71 and 72 are shaped like flat plates, being flush with and apart from each other. As compared with the lead frame 71, the lead frame 72 has a shorter length in the X direction and the same length in the Y direction.

The lead frame 71 includes one base portion 71a. As viewed in the Z direction, the base portion 71a is substantially rectangular and a −X+Y-direction end and a −X−Y-direction corner have a shape cut off obliquely. Six extending portions 71b, 71c, 71d, 71e, 71f, 71g extend from the base portion 71a. As viewed in the +Z direction, the extending portions 71b, 71c, 71d, 71e, 71f, 71g are arranged in this order in a counterclockwise fashion around the base portion 71a and extend from three different sides of the base portion 71a. More specifically, the extending portions 71b and 71c extend from near both X-direction ends of the +Y-direction facing edge of the base portion 71a toward the +Y direction. The extending portions 71d and 71e extend from near both Y-direction ends of the −X-direction facing edge of the base portion 71a toward the −X direction. The extending portions 71f and 71g extend from both X-direction ends of the −Y-direction facing edges of the base portion 71a toward the −Y direction.

A protrusion 71i is formed in a region except for the +X-direction end on a lower surface of the base portion 71a of the lead frame 71. Thus, a region without the protrusion 71i formation on the lower surface of the base portion 71a, i.e., the +X-direction end, is a thin plate portion 71t. As a result, the lead frame 71 has two thickness levels, and the portion of the base portion 71a where the protrusion 71i is formed is a relatively thick plate portion. On the other hand, the thin plate portion 71t of the base portion 71a and the extending portions 71b to 71g are relatively thin plate portions. That is, it is said that the lead frame 71 includes the base portion 71a and the extending portions 71b to 71g as viewed in the Z direction, and includes the thick plate portion and the thin plate portion as viewed in the X direction.

The lead frame 72 includes one base portion 72a. As viewed in the Z direction, the base portion 72a is substantially rectangular and a +X+Y-direction end and a +X−Y-direction corner is cut off obliquely. Four extending portions 72b, 72c, 72d, 72e extend from the base portion 72a. As viewed in the +Z direction, the extending portions 72b, 72c, 72d, 72e are arranged in this order in a clockwise fashion around the base portion 72a and extend from three different sides of the base portion 72a. More specifically, the extending portions 72b extends from the X-direction end of the +Y-direction facing edge of the base portion 71a toward the +Y direction. The extending portions 72c and 72d extend from near both Y-direction ends of the +X-direction facing edge of the base portion 72a toward the +X direction. The extending portions 72e extends from the −X-direction end of the −Y-direction facing edge of the base portion 72a toward the −Y direction.

A protrusion 72i is formed in a region except for the −X-direction end on a lower surface of the base portion 72a of the lead frame 72. Thus, a region without the protrusion 72i formation on the lower surface of the base portion 72a, i.e., the −X-direction end, is a thin plate portion 72t. As a result, likewise the lead frame 71, the lead frame 72 also has two thickness levels, and the portion of the base portion 72a where the protrusion 72i is formed is a relatively thick plate portion. On the other hand, the thin plate portion 72t of the base portion 72a and the extending portions 72b to 72g are relatively thin plate portions. That is, it is said that the lead frame 72 includes the base portion 72a and the extending portions 72b to 71e as viewed in the Z direction, and includes the thick plate portion and the thin plate portion as viewed in the X direction.

In this manner, the protrusions 71i and 72i are formed in regions apart from edges facing each other on each of a lower surface of the lead frame 71 and a lower surface of the lead frame 72. An upper surface 71h of the lead frame 71 and an upper surface 72h of the lead frame 72 are flush with each other, and the lower surface of the protrusion 71i and the lower surface of the protrusion 72i are flush with each other. The position of the upper surface of each extending portion in the Z direction coincides with the position of the upper surface of the lead frames 71 and 72. Hence, each extending portion is located on the same XY plane. In the X direction, the position of the extending portion 71b and the extending portion 71g, the position of the extending portion 71c and the extending portion 71f and the position of the extending portion 72b and the extending portion 72e are identical. In the Y direction, the position of the extending portion 71d and the extending portion 72c and the position of the extending portion 71e and the extending portion 72d are identical.

A line-shaped groove 74 extending in the Y direction is formed in a region corresponding to the base portion 71a on the upper surface 71h of the lead frame 71, that is, a −X-direction region. The groove 74 is formed in a region between the extending portion 71c and the extending portion 71f. Moreover, an L-shaped groove 75 is formed in a region corresponding to the base portion 71a, that is, a +X−Y-direction region. The grove 75 includes a portion 75a extending in the X direction and a portion 75b extending in the Y direction, and an −X-direction end of the portion 75a is connected with a +Y-direction end of the portion 75b. The portion 75b is formed in a region between the extending portion 71b and the extending portion 71g. The grooves 74 and 75 do not pierce through the lead frame 71.

Die mount materials 76a and 76b are attached to part of the region sandwiched between the grooves 74 and 75 in the upper surface of the lead frame 71. The die mount materials 76a and 76b are attached to a rectangular region, respectively. The die mount material 76a is located at −X-direction side and +Y-direction side of the die mount material 76b. In this embodiment, the die mount materials 76a and 76b may be either conductive or insulating. Moreover, a die mount material 77 is attached to the −Y-direction end on the upper surface 72h of the lead frame 72. The die mount material 77 is attached to a rectangular region and the area is smaller than areas of the die mount materials 76a and 76b. The die mount material 77 is conductive.

LED chips 81 and 82 are provided on the die mount materials 76a and 76b, respectively. That is, the die mount materials 76a and 76b secure the LED chips 81 and 82 to the lead frame 71, respectively so that the LED chips 81 and 82 are installed on the lead frame 71. The LED chips 81 and 82 have the same specifications, and are illustratively shaped like a rectangular solid and illustratively square-shaped as viewed in the Z direction. The LED chips 81 and 82 are located so that respective side surfaces are parallel to an XY plane or YZ plane. As viewed from the LED chip 81, the LED chip 82 is located on +X−Y-direction side. Thus, the side surface of the LED chip 81 does not face the side surface of the LED chip 82.

Terminals 81a and 81b are provided on an upper surface of the LED chip 81. The terminal 81a is located in a −X+Y-direction region in the upper surface of the LED chip 81, and the terminal 81b is located in a +X−Y-direction region in the upper surface of the LED chip 81. Moreover, terminals 82a and 82b are provided on the upper surface of the LED chip 82. The terminal 82a is located in a −X+Y-direction region in the upper surface of the LED chip 82, and the terminal 82b is located in a +X−Y-direction region in the upper surface of the LED chip 82.

On the other hand, a Zener diode chip 83 is provided on the die mount material 77. An upper surface terminal 83a is provided on an upper surface of the Zener diode chip 83, and a lower surface terminal (not shown) is provided on a lower surface. That is, the die mount material 77 secures the Zener diode chip 83 to the lead frame 72 so that the Zener diode chip 83 is installed on the lead frame 72 and the lower surface terminal of the Zener diode chip 83 is connected to the lead frame 72.

One end of a wire 85a is bonded to the terminal 81a of the LED chip 81. The wire 85a is extracted from the terminal 81a substantially in the −X direction, curved toward the −Z direction, and another terminal of the wire 85a is bonded to the upper surface 71h of the lead frame 71 substantially in +Z direction. Thus, the terminal 81a of the LED chip 81 is connected to the lead frame 71 via the wire 85a. However, the wire 85a also detours in the Y direction, and an intermediate portion of the wire 85a is misaligned in the +Y direction with respect to an immediately above region of a straight line L1 connecting both ends of the wire 85a.

One end of a wire 85b is bonded to the terminal 81b of the LED chip 81. The wire 85b is extracted from the terminal 81b substantially in the +X direction, curved toward the −Z direction, and another terminal of the wire 85b is bonded to the upper surface 72h of the lead frame 72 substantially in +Z direction. Thus, the terminal 81b of the LED chip 81 is connected to the lead frame 72 via the wire 85b. However, the wire 85b also detours in the Y direction, and an intermediate portion of the wire 85b is misaligned in the −Y direction with respect to an immediately above region of a straight line L2 connecting both ends of the wire 85b.

One end of a wire 86a is bonded to the terminal 82a of the LED chip 82. The wire 86a is extracted from the terminal 82a substantially in the −X direction, curved toward the −Z direction, and another terminal of the wire 86a is bonded to the upper surface 71h of the lead frame 71 substantially in +Z direction. Thus, the terminal 82a of the LED chip 82 is connected to the lead frame 71 via the wire 86a. However, the wire 86a also detours in the Y direction, and an intermediate portion of the wire 86a is misaligned in the +Y direction with respect to an immediately above region of a straight line L3 connecting both ends of the wire 86a.

One end of a wire 86b is bonded to the terminal 82b of the LED chip 82. The wire 86b is extracted from the terminal 82b substantially in the +X direction, curved toward the −Z direction, and another terminal of the wire 86b is bonded to the upper surface 72h of the lead frame 72 substantially in +Z direction. Thus, the terminal 82b of the LED chip 82 is connected to the lead frame 72 via the wire 86b. However, the wire 86b also detours in the Y direction, and an intermediate portion of the wire 86b is misaligned in the −Y direction with respect to a region immediately above a straight line L4 connecting both ends of the wire 86b.

One end of a wire 87 is bonded to the upper terminal 83a of the Zener diode chip 83. The wire 87 is extracted from the upper terminal 83a substantially in the −X direction, curved toward the −Z direction, and another terminal of the wire 87 is bonded to the upper surface 71h of the lead frame 71 substantially in +Z direction. Thus, the upper terminal 83a of the Zener diode chip 83 is connected to the lead frame 71 via the wire 87. However, the wire 87 also detours in the Y direction, and an intermediate portion of the wire 87 is misaligned in the +Y direction with respect to an immediately above region of a straight line L5 connecting both ends of the wire 87. The wires 85a, 85b, 86a, 86b and 87 are formed of a metal, for example, gold or aluminum.

In this manner, a chip side extracting angle 81 when extracting each wire from the LED terminal, i.e., an angle between the upper surface (XY plane) of the lead frame 71 and a direction in which a portion of the wire bonded to the terminal extends is smaller than an angle between the XY plane and a direction in which a portion of the wire bonded to the lead frame extends. An intermediate portion of each wire is located at a position outside a region immediately above the straight line connecting both ends.

As shown in FIG. 35, a bonding position X11 where another terminal of the wire 85a is bonded to the lead frame 71 is located on a −X-direction side as viewed from the groove 74. Similarly, a bonding position X12 where another terminal of the wire 86a is bonded to the lead frame 71 is also located on the −X-direction side as viewed from the groove 74. On the other hand, the die mount materials 76a and 76b are located on a +X-direction side as viewed from the groove 74. That is, the grove 74 is formed between a region where the LED chips 81 and 82 are installed in the upper surface 71h of the lead frame 71 and the positions X11 and X12 where the wires 85a and 86a are bonded. Thus, the positions X11 and X12 where the wires 85a and 86a are bonded to the lead frame 71 are laid out from the die mount materials 76a and 76b by the groove 74.

A bonding position X13 where another terminal of the wire 87 is bonded to the lead frame 71 is located on a −Y-direction side as viewed from the portion 75a of the groove 75. On the other hand, the die mount materials 76a and 76b are located on a +Y-direction side as viewed from the portion 75a. That is, the grove 75 is formed between a region where the LED chips 81 and 82 are installed in the upper surface 71h of the lead frame 71 and the position X13 where the wire 87 is bonded. Thus, the positions X13 where the wire 87 is bonded is laid out from the die mount materials 76a and 76b by the groove 75.

Moreover, the terminal 81a of the LED chip 81 where the one end of the wire 85a is bonded, the position X11 where the another end is bonded, the terminal 81b where the one end of the wire 85b is bonded, the terminal 82a of the LED chip 82 where the one end of the wire 86a is bonded and the position X12 where the another end is bonded are located inside a polygonal region R11 connecting between respective roots of the extending portions 71b, 71c, 71d, 71e, 71f, 71g. In particular, the position X11 is located also inside a square region connecting between the root of the extending portion 71c and the root of the extending portion 71d, and the position X12 is located also inside a square region connecting between the root of the extending portion 71c and the root of the extending portion 71e. That is, the positions X11 and X12 are located inside an overlapping region of the above plurality of regions. Furthermore, the above positions X11 to X13 and the terminals 81a, 81b, 82a, 82b are located in a region immediately above the protrusion 71i.

On the other hand, a position X14 where the another end of the wire 85b is bonded to the lead frame 72, a position X15 where the another end of the wire 86b is bonded to the lead frame 72, the upper surface terminal 83a of the Zener diode chip 83 where the one end of the wire 87 is bonded are located inside a polygonal region R12 connecting between respective roots of the extending portions 72b, 72c, 72d, 72e. The positions X14, X15 and the upper surface terminal 83a are located in a region immediately above the protrusion 72i.

The LED package 9 includes the transparent resin body 17. The shape of the transparent resin body 17 and the relationship to other constituent members are similar to those of the first embodiment described above. That is, an appearance of the resin body is a rectangular solid and is an appearance of the LED package 9. The tip edge surface of each extending portion is exposed on the side surface of the transparent resin body 17, and the lower surface of the protrusions 71i and 72i is exposed on the lower surface of the transparent resin body 17. Portions other than the above portions of the lead frames 71 and 72 are covered with the transparent resin body 17. That is, the lower surfaces and the side surface of each extending portion, the lower surface of the thin plate portions 71t and 72t, the side surface of the base portions 71a and 72a, and the entire surface of the lead frame 71 and 72 are covered with the transparent resin body. The LED chips 81 and 82, the Zener diode 83, the wires 85a, 85b, 86a, 86b and 87 are also covered with the transparent resin body. Numerous phosphors 18 (see FIGS. 2A and 2B) are dispersed inside the transparent resin body 17. The configuration of this embodiment other than the foregoing is similar to that of the above first embodiment.

Next, a method for manufacturing an LED package according to this embodiment is described.

FIG. 39 is a plan view illustrating a lead frame sheet of this embodiment.

The method for manufacturing the LED package according to this embodiment is generally similar to the above first embodiment or the variation. However, as compared with the above first embodiment or the variation, it is different in that the grooves 74 and 75 are formed by half-etching from the upper surface side in fabricating the lead frame sheet.

In other words, as shown in FIG. 9A, the lead frame sheet 23 is fabricated by half-etching. Three blocks B, for instance, are defined in the lead frame sheet 23, and approximate 200 element regions P, for instance, are defined in each block B. As shown in FIG. 39, the element regions P are arranged in a matrix, and the region between the element regions P is a lattice-like dicing region D. In each element region P, a basic pattern including the lead frames 71 and 72 apart from each other is formed. Moreover, the grooves 74 and 75 are formed in the upper surface of the lead frame 71 by half-etching from the upper surface side. The thin plate portions 71t and 72t and bridges 91 to 95 are formed in the lower surface of the lead frames 71 and 72 by half-etching from the lower surface side, and regions without formation of the thin plate portions and bridges are the protrusions 71i and 72i.

Specifically, the bridges 91 and 92 extending in the Y direction through the dicing region D are provided between main portions 71a of the lead frame 71 belonging to the adjacent element regions P in the Y direction. The bridge 91 connects +X-direction portions of the main portion 71a, and the bridge 92 connects −Y-direction portions of the main portion 71a. Similarly, a bridge 93 extending in the Y direction through the dicing region D is provided between main portions 72a of the lead frame 72 belonging to the adjacent element regions P in the Y direction. Moreover, bridges 94 and 95 extending in the X direction through the dicing region D are provided between the main portion 71a of the lead frame 71 and the main portion 72a of the lead frame 72 belonging to adjacent element regions in the X direction. The bridge 94 connects +Y-direction portion of the main portion 71a to +Y-direction portion of the main portion 72a, and the bridge 95 connects −Y-direction portion of the main portion 71a to −Y-direction portion of the main portion 72a. Thus, a total of six bridges (connecting portion) extend in three directions from the main portion 71a of the lead frame 71, and a total of four bridges extend in three directions from the main portion 72a of the lead frame 72.

In a dicing process shown in FIG. 8B, portions of bridges 91 to 95 located in the dicing region D are removed, and thus both end portions of the bridge 91 are the extending portions 71b and 71g, both end portions of the bridge 92 are the extending portions 71c and 71f, both end portions of the bridged 93 are the extending portions 72b and 72e, both end portions of the bridge 94 are the extending portions 71d and 72c, and both end portions of the bridge 95 are the extending portions 71e and 72d. Thus, the portion of the lead frame sheet 23 and the transparent resin plate 29 located in the element regions P is singulated, and the LED package 9 shown in FIGS. 33 to 38 is manufactured. The manufacturing method other than the foregoing of this embodiment is similar to the above first embodiment.

Next, the function and effect of this embodiment are described.

In this embodiment, two LED chips 81 and 82 are connected in parallel between the lead frame 71 and the lead frame 72, and thereby, as compared with the case where only one LED chip is provided, a large amount of light can be obtained. Moreover, in this embodiment, the LED chips 81 and 82 are located obliquely, and the side surface of the LED chip 81 and the side surface of the LED chip 82 are not opposed. Therefore, light emitted from one LED chip does not much enter another LED chip, and the light extraction efficiency from the whole LED package 9 is high. Heat emitted from one LED chip does not much enter another LED chip, which can suppress the decrease of the light emission efficiency due to the temperature increase of another LED chip.

Moreover, in this embodiment, the Zener diode chip 83 is provided, and thus ESD resistance is high.

Furthermore, in this embodiment, the terminal 81a and the terminal 81b of the LED chip 81, the terminal 82a of the LED chip 82, the position X11 and the position X12 are located inside the polygonal region R11 connecting between respective roots of the extending portions 71b, 71c, 71d, 71e, 71f and 71g. This can support stably the bonding position of the wire likewise the first embodiment and thus improves wire bonding performance.

Furthermore, in this embodiment, the groove 74 is formed in the upper surface of the lead frame 71, therefore the position X11 where the wire 85a is bonded and the position X12 where the wire 86a is bonded are laid out from the region where the die mount materials 76a and 76b are attached. The position X13 where the wire 87 is bonded is laid out from the region where the die mount materials 76a and 76b are attached by the groove 75. This can prevent the die mount material from flowing out to the positions X11, X12 and X13 and prevent the region to be bonded to the wire from being contaminated, even if attachment position and attachment amount of the die mount materials 76a and 76b are fluctuated. As a result, in this embodiment, wire bonding reliability is high.

Furthermore, in this embodiment, the chip side extracting angle θ1 of each wire is smaller than the frame side extracting angle θ2. That is, the angle θ1 when extracting the wire from the upper surface of the LED chip located at a relatively higher level is smaller than the angle θ2 when extracting the wire from the upper surface of the lead frame located at a relatively lower level. This can decrease loop height of the wire. Consequently, damage of the wire and its bonding portion due to thermal stress of the transparent resin body 17 can be suppressed and height of the transparent resin body 17 can be decreased.

Furthermore, in this embodiment, the intermediate portion of each wire is located at a position apart from a region immediately above the straight line connecting both ends of the wire. This can give slack in a horizontal direction to the wire and relaxes thermal stress receiving from the transparent resin body. Consequently, wire connecting reliability is improved.

Furthermore, in this embodiment, the base portion has a shape of rectangular solid having a corner portion cut off. Thereby, the corner of the lead frame with a right angle or an acute angle is not provided around corners of the LED package. And the chamfered corner will not serve as the origin of resin peeling and crack of the transparent resin body. As a result, the incidences of resin peeling and crack are suppressed in the LED package as a whole. The function and effect other than the foregoing in this embodiment is similar to those of the above first embodiment.

The invention has been described with reference to the embodiments and the variations thereof. However, the invention is not limited to these embodiments and variations. The above embodiments and the variations thereof can be practiced in combination with each other. Furthermore, those skilled in the art can suitably modify the above embodiments and the variations thereof by addition, deletion, or design change of components, or by addition, omission, or condition change of processes, and such modifications are also encompassed within the scope of the invention as long as they fall within the spirit of the invention.

For instance, in the above first embodiment, the lead frame sheet 23 is illustratively formed by wet etching. However, the invention is not limited thereto, but it may be formed by mechanical means such as press working. Furthermore, on the upper surface of the lead frame, a groove may be formed between the region where a die mount material is to be formed and the region where a wire is to be bonded. Alternatively, on the upper surface of the lead frame, a recess may be formed in the region where a die mount material is to be formed. Thus, even if the supply amount or supply position of the die mount material is varied, it is possible to prevent the die mount material from being spilled to the region intended for wire bonding, and to prevent interference with wire bonding.

Furthermore, in the above first embodiment, in the lead frame, silver plating layers are illustratively formed on the upper and lower surface of the copper plate. However, the invention is not limited thereto. For instance, silver plating layers may be formed on the upper and lower surface of the copper plate, and a rhodium (Rh) plating layer may be formed on at least one of the silver plating layers. Furthermore, a copper (Cu) plating layer may be formed between the copper plate and the silver plating layer. Moreover, a nickel (Ni) plating layer may be formed on the upper and lower surface of the copper plate, and a gold-silver alloy (Au—Ag alloy) plating layer may be formed on the nickel plating layer.

Furthermore, in the above embodiments and the variations thereof, for instance, the LED chip is a chip emitting blue light, the phosphor is a phosphor absorbing blue light and emitting yellow light, so that the color of light emitted from the LED package is white. However, the invention is not limited thereto. The LED chip may be one emitting visible light of a color other than blue, or one emitting ultraviolet or infrared radiation. The phosphor is also not limited to the phosphor emitting yellow light, but may be a phosphor emitting blue light, green light, or red light, for instance.

Phosphors emitting blue light can illustratively include the following.

(RE₁₋ₓSmₓ)₃(Al_{y}Ga_{1-y})₅O₁₂:Ce

where 0≦x<1, 0≦y≦1, and RE is at least one selected from Y and Gd.

ZnS:Ag

ZnS:Ag+Pigment

ZnS:Ag,Al

ZnS:Ag,Cu,Ga,Cl

ZnS:Ag+In₂O₃

ZnS:Zn+In₂O₃

(Ba,Eu)MgAl₁₀O₁₇

(Sr,Ca,Ba,Mg)₁₀(PO₄)₆O₂:Eu

Sr₁₀(PO₄)₆Cl₂:Eu

(Ba,Sr,Eu)(Mg,Mn)Al₁₀O₁₇

10(Sr,Ca,Ba,Eu).6PO₄.Cl₂

BaMg₂Al₁₆O₂₅:Eu

Phosphors emitting green light can illustratively include the following, in addition to the sialon-based green phosphors described above.

ZnS:Cu,Al

ZnS:Cu,Al+Pigment

(Zn,Cd)S:Cu,Al

ZnS:Cu,Au,Al+pigment

Y₃Al₅O₁₂:Tb

Y₃(Al,Ga)₅O₁₂:Tb

Y₂SiO₅:Tb

Zn₂SiO₄:Mn

(Zn,Cd)S:Cu

ZnS:Cu

ZnS:Cu+Zn₂SiO₄:Mn

Gd₂O₂S:Tb

(Zn,Cd)S:Ag

Y₂O₂S:Tb

ZnS:Cu,Al+In₂O₃

(Zn,Cd)S:Ag+In₂O₃

(Zn,Mn)₂SiO₄

BaAl₁₂O₁₉:Mn

(Ba,Sr,Mg)O.aAl₂O₃:Mn

LaPO₄:Ce,Tb

3(Ba,Mg,Eu,Mn)O.8Al₂O₃

La₂O₃.0.2SiO₂.0.9P₂O₅:Ce,Tb

CeMgAl₁₁O₁₉:Tb

Phosphors emitting red light can illustratively include the following, in addition to the sialon-based red phosphors described above.

CaAlSiN₃:Eu²⁺

Y₂O₂S:Eu

Y₂O₂S:Eu+pigment

Y₂O₃:Eu

Zn₃(PO₄)₂:Mn

(Zn,Cd)S:Ag+In₂O₃

(Y,Gd,Eu)BO₃

(Y,Gd,Eu)₂O₃

YVO₄:Eu

La₂O₂S:Eu,Sm

In addition to the silicate-based phosphors described above, the phosphor emitting yellow light can illustratively be a phosphor represented by the general formula MeₓSi₁₂₋₍ₘ₊ₙ₎Al₍ₘ₊ₙ₎OₙN₁₆₋ₙ:Re1_{y}Re2_{z} (where x, y, z, m, and n in the formula are coefficients), where the metal Me (Me being one or two of Ca and Y) solid-solved in the alpha sialon is partly or entirely substituted by a lanthanide metal Re1 (Re1 being one or more of Pr, Eu, Tb, Yb, and Er) serving as an emission center, or by two lanthanide metals Re1 and Re2 (Re2 being Dy) serving as a coactivator.

Furthermore, the color of light emitted entirely from the LED package is not limited to white. An arbitrary tint can be realized by adjusting the weight ratio R:G:B for the red phosphor, green phosphor, and blue phosphor as described above. For instance, white light emission ranging from the white incandescent color to the white fluorescent lamp color can be realized by setting the R:G:B weight ratio to one of 1:1:1-7:1:1, 1:1:1-1:3:1, and 1:1:1-1:1:3.

Furthermore, the phosphor may be omitted from the LED package. In this case, the light emitted from the LED chip is emitted from the LED package.

Still furthermore, in the above-described embodiments, examples have been shown that the base portion of the lead frame has a rectangular shape when seen from above. However, the base portion may have a shape that at least one corner thereof is cut off. Thereby, the corner of the lead frame with a right angle or an acute angle is not provided around corners of the LED package. And the chamfered corner will not serve as the origin of resin peeling and crack of the transparent resin body. As a result, the incidences of resin peeling and crack are suppressed in the LED package as a whole.

According to the embodiments described above, an LED package with high durability and low cost can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. An LED package comprising:
a first lead frame and a second lead frame being apart from each other;
an LED chip provided above the first lead frame and the second lead frame, having one terminal connected to the first lead frame and another terminal connected to the second lead frame;
a wire connecting the one terminal to the first lead frame; and
a resin body covering the first lead frame and the second lead frame, the LED chip and the wire,
the first lead frame including:
a base portion having an upper surface, an edge surface, and a part of a lower surface covered with the resin body and the remaining lower surface exposed on a lower surface of the resin body; and
a plurality of extending portions extending from the base portion, each of the extending portions having a lower surface and an upper surface covered with the resin body and an edge surface exposed on a side surface of the resin body,
a bonding position of the wire being located inside one of polygonal regions connecting between roots of the two or more of the extending portions, and
an appearance of the resin body being a part of an appearance of the LED package.

2. The package according to claim 1, wherein
the first lead frame is provided with the three or more extending portions extending in three different directions, and
the bonding position of the wire is located inside one of polygonal regions connecting between roots of three of the extending portions.

3. The package according to claim 1, wherein, the bonding position of the wire is located inside an overlapping region of a plurality of the polygonal regions, and the bonding position is located inside a region where the lower surface of the first lead frame is exposed on the lower surface of the resin body.

4. The package according to claim 1, further comprising another wire connecting the another terminal to the second lead frame, wherein
the second lead frame includes:
a base portion having an upper surface, an edge surface, and a part of a lower surface covered with the resin body and the remaining lower surface exposed on a lower surface of the resin body; and
a plurality of extending portions extending from the base portion, each of the extending portions having a lower surface and an upper surface covered with the resin body and an edge surface exposed on a side surface of the resin body,
a bonding position of the another wire is located inside one of polygonal regions connecting between roots of two or more of the extending portions of the second lead frame.

5. The package according to claim 1, wherein at least one surface of an upper surface and a lower surface of the first lead frame has a roughness of substantially 1.20 or more and at least one surface of an upper surface and a lower surface of the second lead frame has a roughness of substantially 1.20 or more.

6. The package according to claim 1, wherein a shortest distance between the edge surface of the base portion and the side surface of the resin body is substantially 50% or more of a maximum thickness of the first lead frame and the second lead frame.

7. The package according to claim 1, wherein
the first lead frame and the second lead frame have a first edge and a second edge respectively, the first edge and the second edge face each other, the first protrusion is formed in a region being apart from the first edge, and the second protrusion is formed in a region being apart from the second edge, and
a lower surface of the first protrusion and a lower surface of the second protrusion are exposed on the lower surface of the resin body, and a side surface of the first protrusion and a side surface of the second protrusion are covered with the resin body.

8. The package according to claim 1, further comprising:
a phosphor located in the resin body,
the LED chip emitting blue light, and the phosphor being a phosphor absorbing the blue light and emitting green light and a phosphor absorbing the blue light and emitting red light.

9. The package according to claim 1, wherein the LED chip is provided in a plurality and the plurality of the LED chips are arranged in a zigzag alignment.

10. The package according to claim 1, wherein the LED chip is provided in two and the two LED chips are located so that a side surface of one of the LED chips and a side surface of another one of the LED chips not facing each other.

11. The package according to claim 1, further comprising a Zener diode chip provided above the first lead frame and the second lead frame, having one terminal connected to the first lead frame and another terminal connected to the second lead frame,
the LED chip being mounted on the first lead frame, and
a groove being formed between a region mounted with the LED chip and a position bonded to the wire on an upper surface of the first lead frame.

12. The package according to claim 1, wherein
the one terminal is provided on an upper surface of the LED chip,
an angle between an upper surface of the first lead frame and a direction in which a portion of the wire bonded to the one terminal extends is smaller than an angle between the upper surface of the first lead frame and a direction in which a portion of the wire bonded to the first lead frame extends.

13. The package according to claim 1, wherein the base portion has a rectangular shape having a corner cut off.

14. An LED package comprising:
a first lead frame and a second lead frame being apart from each other;
an LED chip provided above the first lead frame and the second lead frame, having one terminal connected to the first lead frame and another terminal connected to the second lead frame; and
a resin body covering the first lead frame, the second lead frame, and the LED chip,
the first lead frame including:
a base portion having an upper surface, an edge surface, and a part of a lower surface covered with the resin body and the remaining lower surface exposed on a lower surface of the resin body; and
extending portions extending from the base portion, each of the extending portions having a lower surface and an upper surface covered with the resin body and an edge surface exposed on a side surface of the resin body,
a shortest distance between the edge surface of the base portion and the side surface of the resin body being substantially 50% or more of a maximum thickness of the first lead frame, and
an appearance of the resin body being a part of an appearance of the LED package.

15. The package according to claim 14, wherein at least one surface of an upper surface and a lower surface of the first lead frame has a roughness of substantially 1.20 or more and at least one surface of an upper surface and a lower surface of the second lead frame has a roughness of substantially 1.20 or more.

16. The package according to claim 14, wherein
the first lead frame and the second lead frame have a first edge and a second edge respectively, the first edge and the second edge face each other, the first protrusion is formed in a region being apart from the first edge, and the second protrusion is formed in a region being apart from the second edge, and
a lower surface of the first protrusion and a lower surface of the second protrusion are exposed on the lower surface of the resin body, and a side surface of the first protrusion and a side surface of the second protrusion are covered with the resin body.

17. The package according to claim 14, wherein the LED chip is provided in two and the two LED chips are located so that a side surface of one of the LED chips and a side surface of another one of the LED chips not facing each other.

18. The package according to claim 14, further comprising a Zener diode chip provided above the first lead frame and the second lead frame, having one terminal connected to the first lead frame and another terminal connected to the second lead frame,
the LED chip being mounted on the first lead frame, and
a groove being formed between a region mounted with the LED chip and a position connected to the wire on an upper surface of the first lead frame.

19. The package according to claim 14, wherein
the one terminal is provided on an upper surface of the LED chip,
an angle between an upper surface of the first lead frame and a direction in which a portion of the wire bonded to the one terminal extends is smaller than an angle between the upper surface of the first lead frame and a direction in which a portion of the wire bonded to the first lead frame extends.

20. The package according to claim 14, wherein the base portion has a rectangular shape having a corner cut off.
